(19) United States
(12) Patent Application Publication
(10) Pub. No.: US 2025/0131230 A1
(43) Pub. Date: Apr. 24, 2025

(54) FINGERPRINT SENSOR PACKAGE CARRIER AND FINGERPRINT SENSOR PACKAGE ASSEMBLY METHOD

(71) Applicant: SAMSUNG ELECTRONICS CO., LTD., SUWON-SI (KR)

(72) Inventors: Yechung CHUNG, Suwon-si (KR); Woonbae KIM, Suwon-si (KR); Youngjun YOON, Suwon-si (KR); Soyoung LIM, Suwon-si (KR); Jaehyun LIM, Suwon-si (KR); Inho CHOI, Suwon-si (KR)

(21) Appl. No.: 18/672,381

(22) Filed: May 23, 2024

(30) Foreign Application Priority Data
Oct. 18, 2023 (KR) 10-2023-0139185

(51) Int. Cl. G06K 19/07; G06K 19/077; G06V 40/13

(52) U.S. Cl. CPC G06K 19/0718; G06K 19/07713; G06V 40/1306

(57) ABSTRACT

A fingerprint sensor package carrier includes: a film member including through-holes formed in sides of the film member; and a plurality of fingerprint sensor packages arranged on the film member, wherein each of the plurality of fingerprint sensor packages includes a substrate and a controller chip disposed on the substrate, wherein the substrate of each of the plurality of fingerprint sensor packages includes a plurality of first sensing patterns and a plurality of second sensing patterns, wherein the plurality of first sensing patterns are spaced apart from each other in a first direction and extend in a second direction intersecting the first direction, and the plurality of second sensing patterns are spaced apart from each other in the second direction and extend in the first direction, and wherein the film member has adhesiveness, such that the plurality of fingerprint sensor packages are configured to be detached from the film member.

### CROSS-REFERENCE TO RELATED APPLICATION

This application claims priority under 35 U.S.C. § 119 to Korean Patent Application No. 10-2023-0139185 filed on Oct. 18, 2023 in the Korean Intellectual Property Office, the disclosure of which is incorporated by reference herein in its entirety.

### TECHNICAL FIELD

Example embodiments of the present inventive concept relate to a fingerprint sensor package carrier and a fingerprint sensor package assembly method.

### DISCUSSION OF THE RELATED ART

Fingerprint recognition technology has been used to prevent various security incidents by recognizing a fingerprint of a user and going through registration and authentication processes. For example, this technology may be applied to individual and organizational network defense, may provide protection of various contents and data, and may provide safe access to financial information. A fingerprint sensor may obtain fingerprint information of a user using optical, capacitive, ultrasonic, or thermal detection methods. Moreover, a recent trend in the fingerprint sensor industry has been to continuously miniaturize products while reducing costs thereof. Accordingly, a fingerprint sensor package with increased reliability and sensitivity for obtaining fingerprint information, with reduced size and height, and reduced manufacturing costs has been under development.

### SUMMARY

According to an example embodiment of the present inventive concept, a fingerprint sensor package carrier includes: a film member including a plurality of through-holes formed in sides of the film member; and a plurality of fingerprint sensor packages arranged between the sides of the film member, wherein each of the plurality of fingerprint sensor packages includes a substrate and a controller chip disposed on the substrate, wherein the substrate of each of the plurality of fingerprint sensor packages includes a plurality of first sensing patterns and a plurality of second sensing patterns, wherein the plurality of first sensing patterns are spaced apart from each other in a first direction and extend in a second direction intersecting the first direction, and the plurality of second sensing patterns are spaced apart from each other in the second direction and extend in the first direction, and wherein the film member has adhesiveness, such that the plurality of fingerprint sensor packages are configured to be detached from the film member.

According to an example embodiment of the present inventive concept, a fingerprint sensor package carrier includes: a film member including a film, a release layer disposed on the film, and an adhesive layer disposed between the release layer and the film; and a plurality of fingerprint sensor packages arranged on the film member, wherein each of the plurality of fingerprint sensor packages includes a controller chip and a substrate disposed between the controller chip and the film member, and wherein the substrate of each of the plurality of fingerprint sensor packages has a plurality of first sensing patterns and a plurality of second sensing patterns, wherein the plurality of first sensing patterns are spaced apart from each other in a first direction and extend in a second direction intersecting the first direction, and the plurality of second sensing patterns are spaced apart from each other in the second direction and extend in the first direction.

According to an example embodiment of the present inventive concept, a fingerprint sensor package assembly method includes: detaching a fingerprint sensor package from a film member, wherein the fingerprint sensor package includes a substrate, a controller chip disposed on the substrate, and a molding layer covering the controller chip; and disposing the fingerprint sensor package in a groove region of a device body, wherein a horizontal size of a portion of the fingerprint sensor package, other than the molding layer, before being detached from the film member is the same as a horizontal size of the portion of the fingerprint sensor package, other than the molding layer, after being disposed in the groove region of the device body.

### BRIEF DESCRIPTION OF DRAWINGS

The above and other aspects of the present inventive concept will become more apparent by describing in detail example embodiments thereof, with reference to the accompanying drawings, in which:

FIGS. 1A, 1B, 1C, 1D and 1E are diagrams illustrating a fingerprint sensor package carrier according to an example embodiment of the present inventive concept;

FIGS. 2A, 2B, 2C and 2D are diagrams illustrating a fingerprint sensor package assembly method according to an example embodiment of the present inventive concept;

FIGS. 3A, 3B, 3C, 3D, 3E, 3F, and 3G are cross-sectional diagrams illustrating a fingerprint sensor package carrier and a fingerprint sensor package assembly method according to an example embodiment of the present inventive concept;

FIGS. 4A, 4B and 4C are cross-sectional diagrams illustrating a fingerprint sensor package carrier according to an example embodiment of the present inventive concept; and

FIGS. 5A, 5B, 5C, 5D and 5E are cross-sectional diagrams illustrating a fingerprint sensor package carrier according to an example embodiment of the present inventive concept.

### DETAILED DESCRIPTION OF THE EMBODIMENTS

Hereinafter, example embodiments of the present inventive concept will be described as follows with reference to the accompanying drawings.

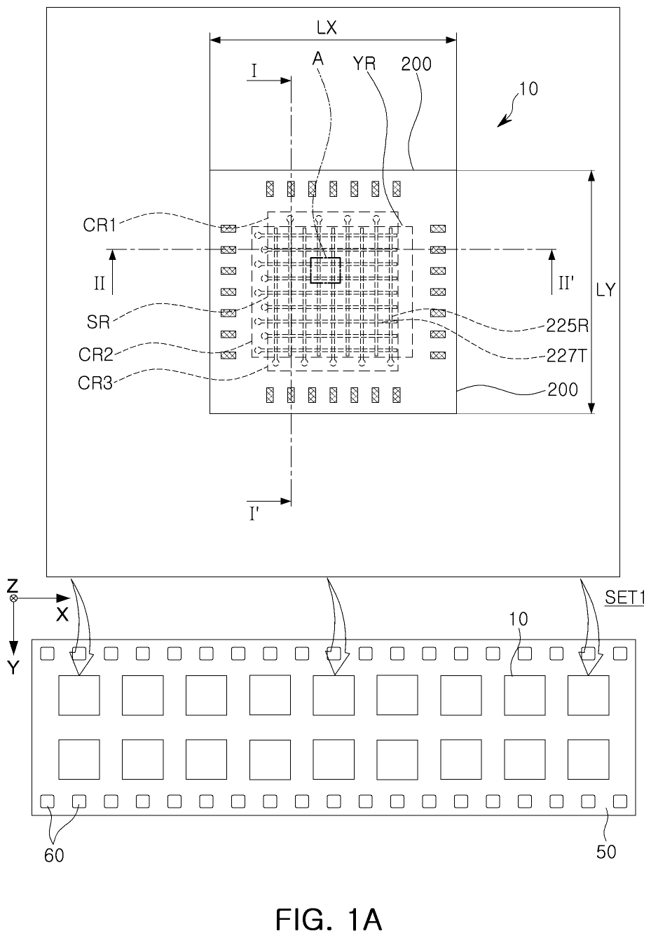

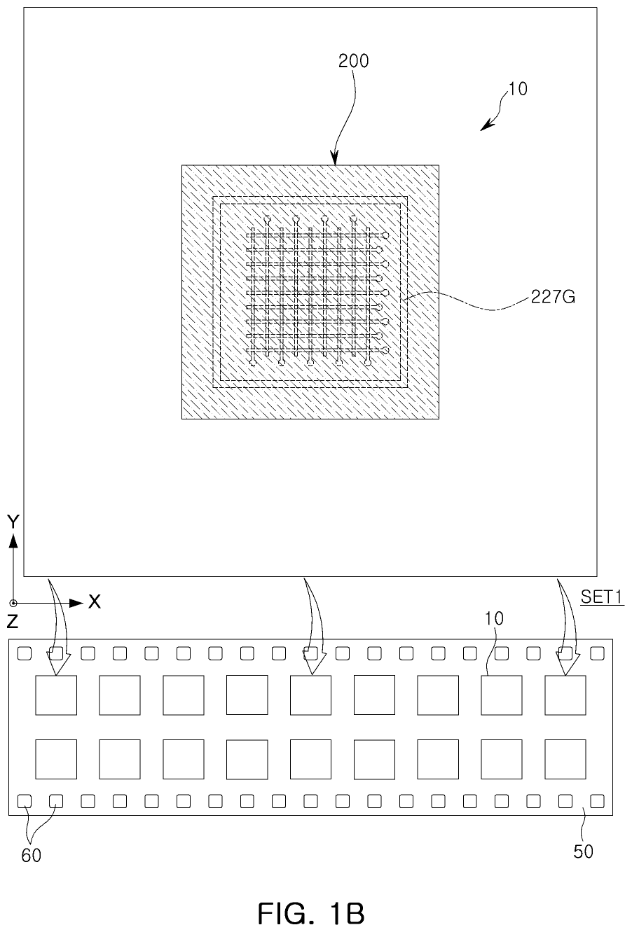

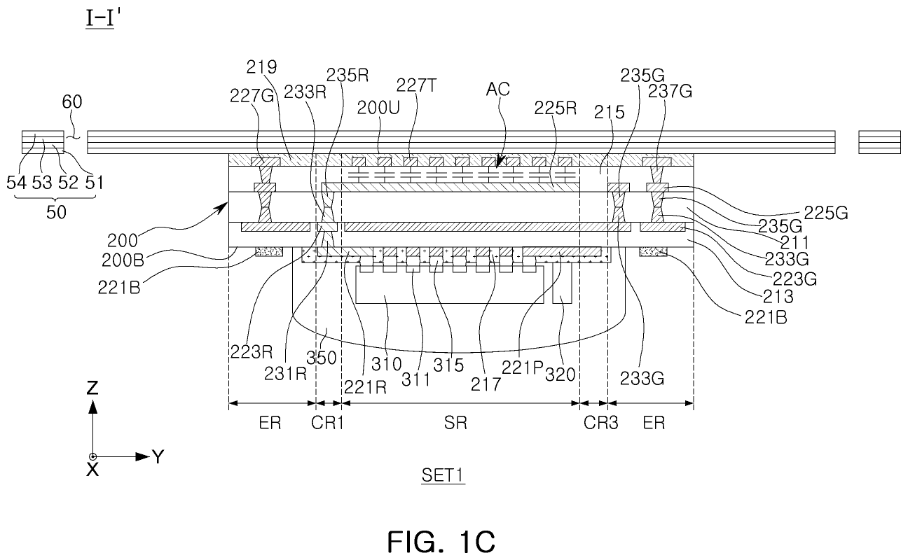

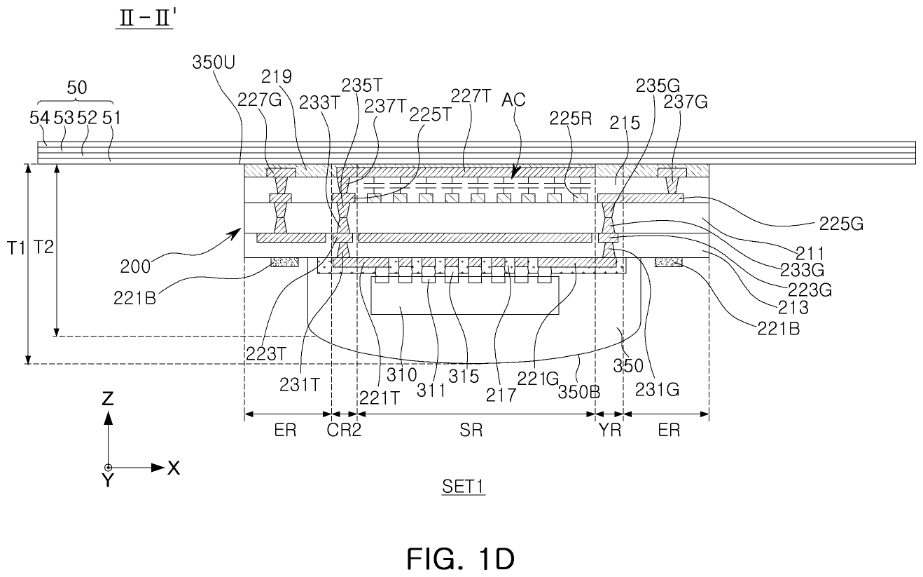

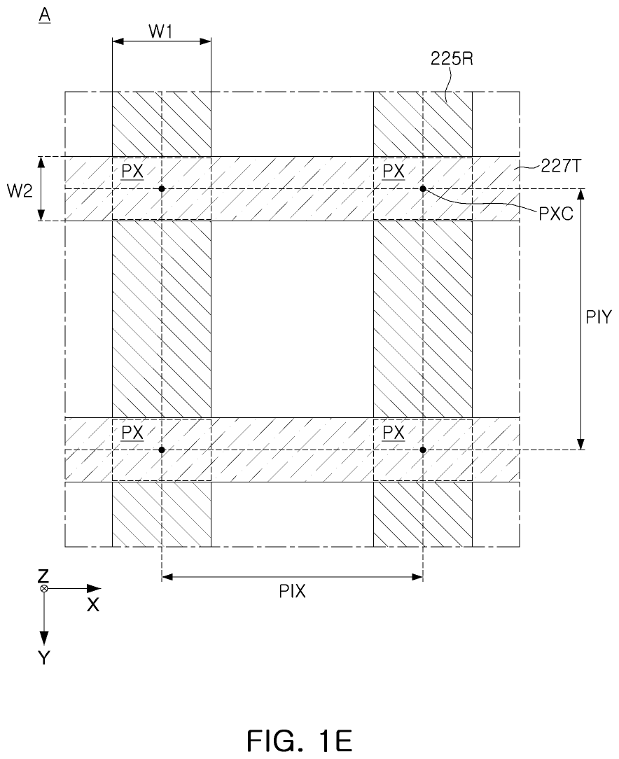

FIG. 1A is a diagram illustrating a layout of a fingerprint sensor package carrier SET1, viewed from below. FIG. 1B is a plan diagram illustrating the fingerprint sensor package carrier SET1 in FIG. 1A. FIG. 1C is a cross-sectional diagram taken along line I-I′ in FIG. 1A. FIG. 1D is a cross-sectional diagram taken along line II-II′ in FIG. 1A. FIG. 1E is an enlarged diagram illustrating a region “A” in FIG. 1A.

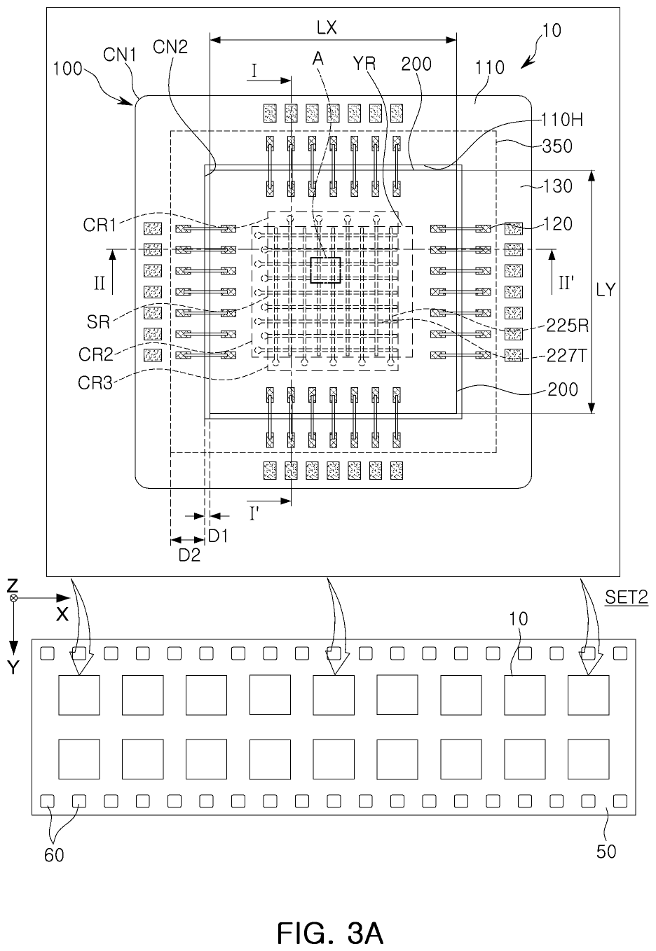

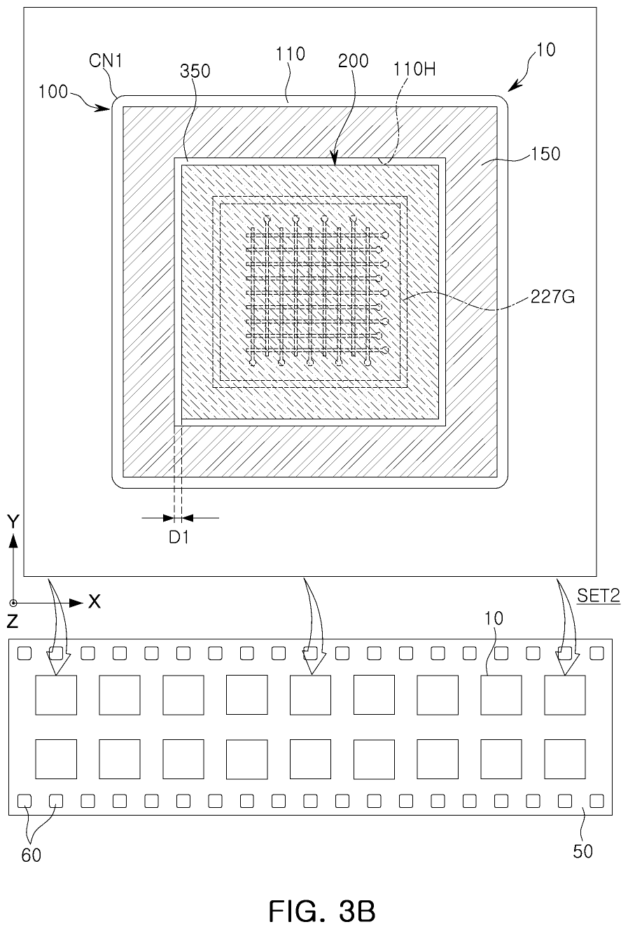

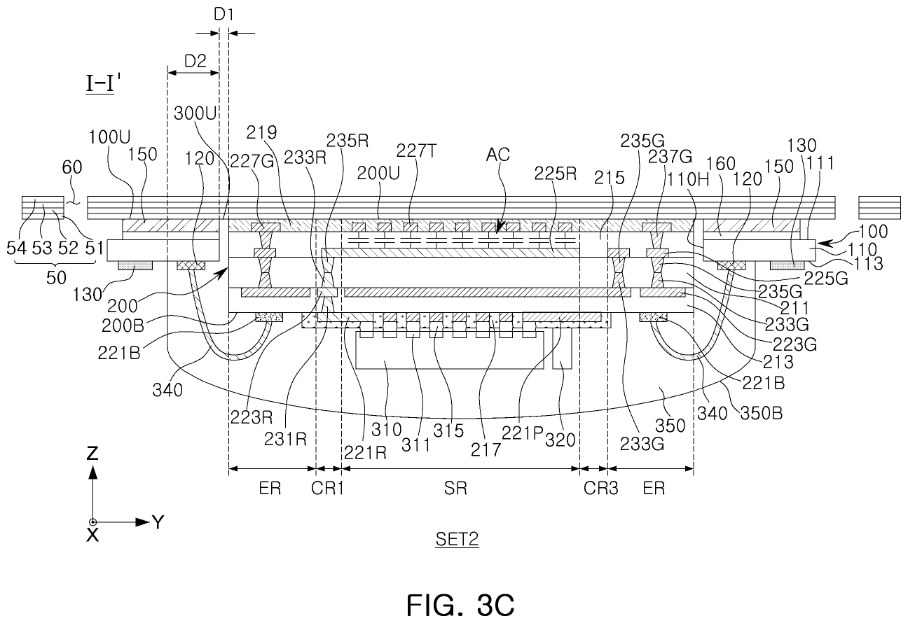

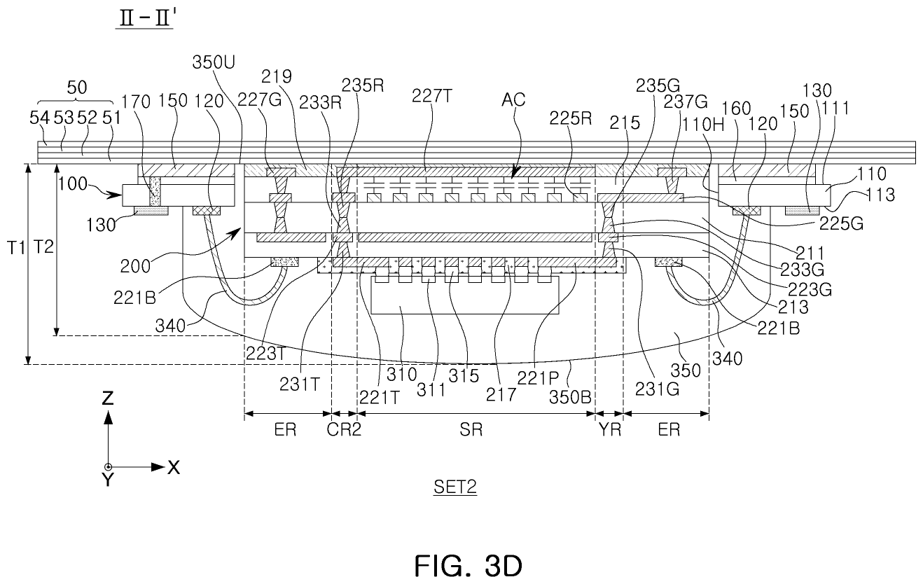

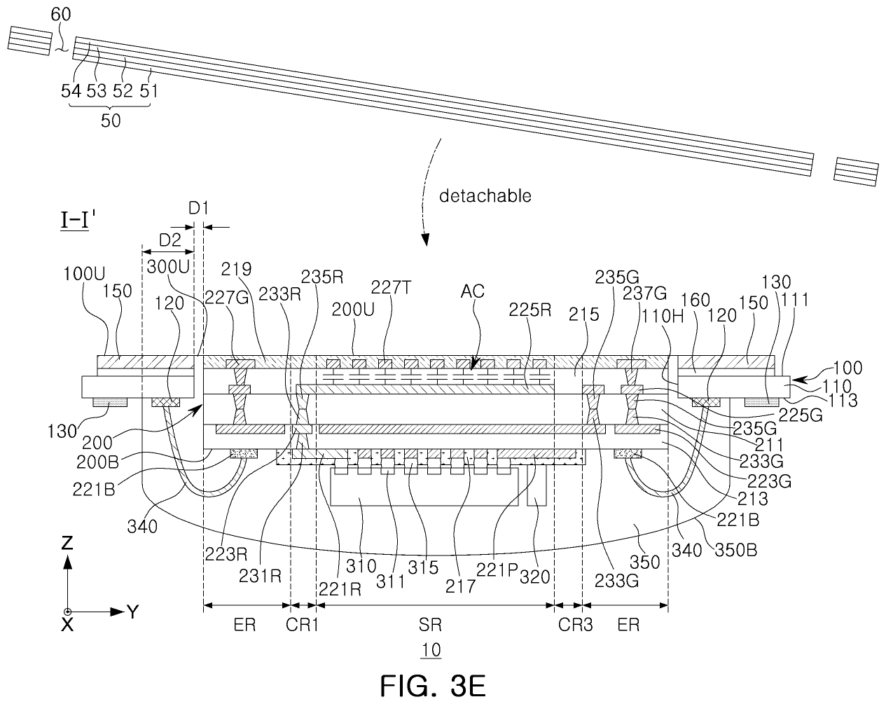

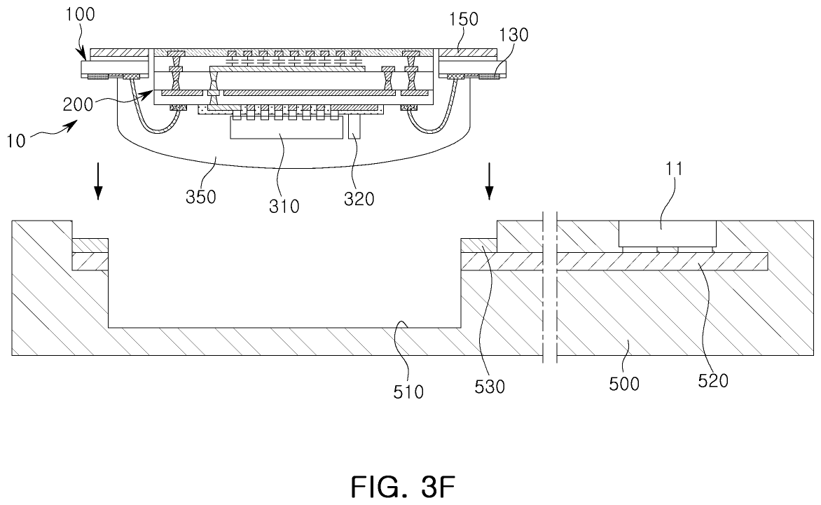

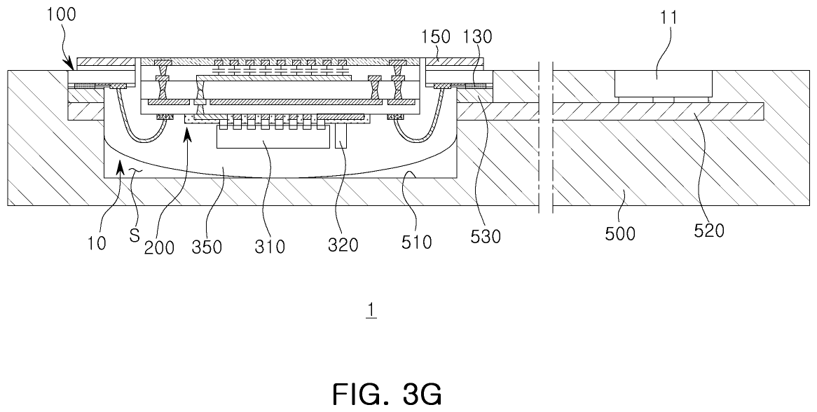

Referring to FIGS. 1A to 1E, the fingerprint sensor package carrier SET1 according to an example embodiment of the present inventive concept may include a plurality of fingerprint sensor packages 10 and a film member 50. Each of the plurality of fingerprint sensor packages may include a substrate 200 and a controller chip 310 that is disposed on the substrate 200. In example embodiments of the present inventive concept, each of the plurality of fingerprint sensor packages 10 may further include at least one of a passive component 320, conductive wires 340 (see FIGS. 3C, 3D, 3E, 4A, 4B, 4C, 5A, 5B, 5C, 5D, and 5E) and a first molding layer 350.

The film member 50 may have a plurality of through-holes 60 formed in both sides (e.g., Y-direction side) thereof. Accordingly, the film member 50 may be efficiently provided to an infrastructure for assembling a plurality of fingerprint sensor packages 10 into corresponding devices in a reel-to-reel manner. For example, teeth of a sprocket included in the infrastructure may be inserted into the plurality of through-holes 60, and the sprocket may wind or unwind the film member 50 by rotating. The size, shape, density and arrangement direction of the plurality of through-holes 60 may vary depending on the sprocket. For example, an area of each of the plurality of through-holes 60 may be smaller than an area of an upper surface (e.g., a surface in direct contact with the film member 50) of each of the substrates 200, and a shape of each of the plurality of through-holes 60 may be circular or polygonal (including a polygon having chamfered corners). The plurality of through-holes 60 may be defined as sprocket holes, but an example embodiment of the present inventive concept is not limited thereto.

When the film member 50 is wound or unwound by the sprocket, the plurality of fingerprint sensor packages 10 may be provided flexibly by being attached to the film member 50. Subsequently, the plurality of fingerprint sensor packages 10 may be detached from the film member 50 for assembly into devices. When the plurality of fingerprint sensor packages 10 are separated from the film member 50 by cutting edges of the plurality of fingerprint sensor packages 10, the plurality of fingerprint sensor packages 10 may be exposed to the risk of being damaged or decreased reliability during a cutting process (e.g. a punching process), and the risk of a changed horizontal size due to process dispersion during the cutting process. The change of horizontal size due to process distribution may reduce efficiency/reliability of assembling the plurality of fingerprint sensor packages 10 into devices. In addition, the cutting process may also increase costs.

The film member 50 may have adhesiveness, such that the plurality of fingerprint sensor packages 10 may be detached from the film member 50. Accordingly, the plurality of fingerprint sensor packages 10 may be efficiently detached from the film member 50 without a cutting process for the plurality of fingerprint sensor packages 10. Accordingly, the plurality of fingerprint sensor packages 10 may be prevented from being damaged during a cutting process and/or reliability may be prevented from being deteriorated. In addition, the change of horizontal size due to process distribution during the cutting process may be prevented, and costs of the cutting process may be reduced.

For example, the film member 50 may be configured such that the plurality of fingerprint sensor packages 10 may be detached from the film member 50 as adhesiveness of the film member 50 may be weakened by ultraviolet rays. Accordingly, there may be almost no physical force required to detach the plurality of fingerprint sensor packages 10 from the film member 50, such that the possibility of reliability degradation while detaching the plurality of fingerprint sensor packages 10 may be further reduced. For example, at least a portion of the film member 50 may be implemented as UV (ultraviolet) tape.

For example, the film member 50 may include at least one of a film 54, a release layer 51 disposed on the film 54, an adhesive layer 52 disposed between the release layer 51 and the film 54, and a resin layer 53 disposed between the adhesive layer 52 and the film 54, and at least one of the film 54, the release layer 51, the adhesive layer 52 and the resin layer 53 may have a plurality of through-hole 60. Since the adhesive layer 52 may have a higher degree of adhesiveness than that of the release layer 51 and the film 54, the adhesive layer 52 may bond upper and lower surfaces of adhesive layer 52 to each other. Adhesiveness of the adhesive layer 52 may be weakened by ultraviolet rays. The release layer 51 and the film 54 may have high ductility and/or high durability. The resin layer 53 may be used optionally and may strongly connect the film 54 and the adhesive layer 52 to each other.

For example, the film 54 may be a polyethylene terephthalate (PET) film or a polyolefin (PO) film. For example, the release layer 51 may be a PET layer or a polyester layer, and the adhesive layer 52 may be an acrylic layer or an epoxy resin layer of which adhesiveness may be weakened by ultraviolet rays, but an example embodiment thereof is not limited thereto. For example, each of the film 54, the release layer 51, the adhesive layer 52 and the resin layer 53 may include synthetic resins such as polyimide, epoxy resin, acrylic, polyethylene terephthalate (PET), polyolefin (PO), polyvinyl chloride, polyether nitrile, polyether sulfone, and polyethylene naphthalate.

The substrate 200 may be disposed between the controller chip 310 and the film member 50. For example, the substrate 200 may be directly attached to and in contact with the film member 50, and the substrate 200 may be directly detached from the film member 50. An upper surface of the substrate 200 may be approached by a finger having a fingerprint, such that the surface may be relatively wide and flat. Accordingly, an upper surface of the substrate 200 may be efficiently attached to and detached from the film member 50 by adhesiveness of the film member 50. For example, the substrate 200 may be configured as a printed circuit board (PCB), which may include an upper protective layer 219 such as a solder resist, and the upper protective layer 219 may be efficiently attached to and detached from the film member 50 by adhesiveness of the film member 50. In addition, the upper protective layer 219 such as solder resist may be pre-cured by ultraviolet rays and may be robust against ultraviolet rays in a pre-cured state. Accordingly, when the film member 50 is configured to be detached by using ultraviolet rays, such as a UV tape, the upper protective layer 219 of the substrate 200 may reduce a possibility of reducing reliability of the plurality of the first sensing pattern 225R and the plurality of second sensing patterns 227T while being detached from the film member 50.

The substrate 200 may have a substantially rectangular planar shape or a square planar shape. The substrate 200 may include an upper surface 200U and a lower surface 200B opposing each other. The upper surface 200U of the substrate 200 may be touched by a fingerprint of a user for fingerprint recognition, and components such as the controller chip 310 may be mounted on the lower surface 200B of substrate 200. A first length LX of the substrate 200 in the first direction (X-direction) may range from about 10 mm to about 15 mm. In addition, a second length LY of the substrate 200 in the second direction (Y-direction) may range from about 10 mm to about 15 mm. For example, the first length LX of substrate 200 may be about 12.7 mm, and the second length LY may be about 12.7 mm.

Referring to FIG. 1A, the substrate 200 may include a sensing region SR, a first contact region CR1, a second contact region CR2, a third contact region CR3, a wiring region YR, and a peripheral region ER.

Referring to FIG. 1C, the substrate 200 may include a base layer 211, a lower insulating layer 213 on a surface of the base layer 211, an upper insulating layer 215 on an upper surface of the base layer 211, a lower protective layer 217 on a surface of the lower insulating layer 213, and an upper protective layer 219 on an upper surface of the upper insulating layer 215.

The substrate 200 may include a PCB. In example embodiments of the present inventive concept, the substrate 200 may include a rigid-type substrate.

In addition, the substrate 200 may be configured as a PCB having a multilayer structure including a plurality of conductive layers. The substrate 200 may include conductive layers, which are disposed on different vertical levels, and conductive vias that are electrically connect the conductive layers to each other. For example, the conductive layers and the conductive vias may each include at least one of copper (Cu), aluminum (Al), nickel (Ni), silver (Ag), gold (Au), platinum (Pt), tin (Sn), lead (Pb), titanium (Ti), chromium (Cr), Palladium (Pd), indium (In), zinc (Zn), carbon (C), and their alloys.

For example, the substrate 200 may include first conductive layers 221B, 221G, 221R, 221T, and 221P, second conductive layers 223G and 223R, and 223T, third conductive layers 225G and 225R, and 225T, and fourth conductive layers 227G and 227T in order of decreasing a distance from the upper surface 200U. The first conductive layers 221B, 221G, 221R, 221T, and 221P may be present on a surface of the lower insulating layer 213. The second conductive layers 223G and 223R, and 223T may be present on a surface of the base layer 211, and the third conductive layers 225G and 225R, and 225T may be present on an upper surface of the base layer 211. The fourth conductive layers 227G and 227T may be present on an upper surface of the upper insulating layer 215.

The first conductive layer 221B, 221G, 221R, 221T, and 221P may include second bonding pads 221B, 1-1 sensing pads 221R, 1-2 sensing pads 221T, a first ground pattern 221G, and a power pattern 221P. The second conductive layer 223G and 223R, and 223T may include 2-1 sensing pads 223R, 2-2 sensing pads 223T, and a second ground pattern 223G. The third conductive layer 225G and 225R, and 225T may include first sensing patterns 225R, 3-2 sensing pads 225T, and a third ground pattern 225G. The fourth conductive layer 227G and 227T may include second sensing patterns 227T and a fourth ground pattern 227G.

The conductive vias 231R, 233R, and 235R may be spaced apart from the ground pattern 223G, and may electrically connect the plurality of first sensing patterns 225R and the plurality of second sensing patterns 227T to the controller chip 310. The ground pattern 223G may be disposed between the lower insulating layer 213 and the base layer 211 and may vertically overlap the controller chip 310. Accordingly, the ground pattern 223G may increase electromagnetic isolation between the first and second sensing patterns 225R and 227T and the controller chip 310 and may reduce noise of signals of the first and second sensing patterns 225R and 227T.

In addition, the substrate 200 may include first conductive vias 231G, 231R, and 231T for electrically connecting the first conductive layer 221B, 221G, 221R, 221T, and 221P to the second conductive layer 223G and 223R, and 223T. The substrate 200 may further include second conductive vias 233G, 233R, and 233T and third conductive vias 235G, 235R, and 235T for electrically connecting the second conductive layer 223G and 223R, and 223T to the third conductive layer 225G and 225R, and 225T The substrate 200 may additionally include fourth conductive vias 237T and 237G for electrically connecting the third conductive layer 225G and 225R, and 225T to the fourth conductive layer 227G and 227T. The first conductive vias 231G, 231R, and 231T may at least partially penetrate through the lower insulating layer 213, and the second conductive vias 233G, 233R, and 233T may partially penetrate through the base layer 211. The third conductive vias 235G, 235R, and 235T may partially penetrate through the base layer 211, and the fourth conductive vias 237T and 237G may at least partially penetrate through the upper insulating layer 215.

The first conductive vias 231G, 231R, and 231T may include 1-1 sensing vias 231R for electrically connecting the 1-1 sensing pads 221R to the 2-1 sensing pads 223R, 1-2 sensing vias 231T for electrically connecting the 1-2 sensing pads 221T to the 2-2 sensing pads 223T, and a first ground via 231G for electrically connecting the first ground pattern 221G to the second ground pattern 223G. In example embodiments of the present inventive concept, the first conductive vias 231G, 231R and 231T may have a tapered structure.

The second conductive vias 233G, 233R, and 233T may include a 2-1 sensing vias 233R for electrically connecting the 2-1 sensing pads 223R to the first sensing patterns 225R, 2-2 sensing vias 233T for electrically connecting the 2-2 sensing pads 223T to the 3-2 sensing pads 225T, and a second ground via 233G for electrically connecting the second ground pattern 223G to the third ground pattern 225G. The third conductive vias 235G, 235R, and 235T may include 3-1 sensing vias 235R for electrically connecting the sensing pads 223R to the first sensing patterns 225R, 3-2 sensing vias 235T for electrically connecting the 2-2 sensing pads 223T to the 3-2 sensing pads 225T, and a third ground via 235G for electrically connecting the second ground pattern 223G to the third ground pattern 225G.

The second conductive vias 233G, 233R, and 233T may be in contact with the second conductive layer 223G and 223R, and 223T, respectively. The third conductive vias 235G, 235R, and 235T may be in contact with the third conductive layer 225G and 225R, and 225T, respectively, and the second conductive vias 233G, 233R, and 233T and the third conductive vias 235G, 235R, and 235T may be in contact with each other, respectively. Specifically, the 2-1 sensing pads 223R and the first sensing patterns 225R may be electrically connected to each other through the 2-1 sensing vias 233R and the 3-1 sensing vias 235R which are vertically connected to each other, and the 2-2 sensing pads 223T and the 3-2 sensing pads 225T may be electrically connected to each other through the 2-2 sensing vias 233T and the 3-2 sensing vias 235T which are vertically connected to each other. The second ground pattern 223G and the third ground pattern 225G may be electrically connected to each other through the second ground via 233G and the third ground via 235G, which are vertically connected to each other.

In example embodiments of the present inventive concept, each of the second conductive vias 233G, 233R, and 233T and the third conductive vias 235G, 235R, and 235T may have a tapered structure in which a horizontal width may decrease as a center of the base layer 211 is approached in a thickness direction. In example embodiments of the present inventive concept, the second conductive vias 233G, 233R, and 233T and the third conductive vias 235G, 235R, and 235T may have a minimum horizontal width at a contact surface therebetween.

The fourth conductive vias 237T and 237G may include 4-2 sensing vias 237T for electrically connecting the 3-2 sensing pads 225T to the second sensing patterns 227T, and a fourth ground via 237G for electrically connecting the third ground pattern 225G to the fourth ground pattern 227G. In example embodiments of the present inventive concept, the fourth conductive vias 237T and 237G may have a tapered structure in which a horizontal width decreases as the base layer 211 is approached in a thickness direction.

Referring to FIG. 1A, the substrate 200 may include a sensing region SR, a first contact region CR1, a second contact region CR2, a third contact region CR3, a wiring region YR, and a peripheral region ER. For example, in the sensing region SR, the first and second sensing patterns 225R and 227T for fingerprint recognition may be disposed. Referring to FIG. 1C, in the first contact region CRI and the third contact region CR3, 1-1 sensing vias 231R, 2-1 sensing vias 233R, and 3-1 sensing vias 235R may be disposed for connecting the first sensing patterns 225R to the controller chip 310. In the second contact region CR2, the 1-2 sensing vias 231T, the 2-2 sensing vias 233T, the 3-2 sensing vias 235T, and the 4-2 sensing vias 237T may be disposed for connecting the second sensing patterns 227T to the controller chip 310a. In the wiring region YR, at least a portion of the first to fourth ground vias 231G, 233G, 235G, and 237G for connecting the fourth ground pattern 227G to the controller chip 310 may be disposed.

Referring to FIGS. 1A and 1E, the sensing region SR may be disposed in a central portion of the substrate 200. In example embodiments of the present inventive concept, the sensing region SR may have a rectangular shape or a square shape in a plan view. A plurality of first sensing patterns 225R having a line shape, which are spaced apart from each other in the first direction (X-direction) and extending in the second direction (Y-direction), may be disposed in the sensing region SR. In addition, a plurality of second sensing patterns 227T having a line shape, which are spaced apart from each other in the second direction (Y-direction) and extending in the first direction (X-direction), may be disposed in the sensing region SR.

The first contact region CR1 may be formed at one end of the sensing region SR in the second direction (Y-direction), and the third contact region CR3 may be formed at another end of the sensing region SR in the second direction (Y-direction). For example, the first contact region CR1 and the third contact region CR3 may be respectively disposed at opposite ends of the sensing region SR. In addition, the second contact region CR2 may be formed on one end of the sensing region SR in the first direction (X-direction), and the wiring region YR may be formed in another end of the sensing region SR in the first direction (X-direction). For example, the second contact region CR2 and the wiring region YR may be respectively disposed at opposite ends of the sensing region SR.

The peripheral region ER may be disposed in an outer portion of the substrate 200. The peripheral region ER may surround the sensing region SR, the first through third contact regions CR1, CR2, and CR3, and the wiring region YR, in a plan view. Second bonding pads 221B may be disposed in the peripheral region ER. The first to fourth ground patterns 221G, 223G, 225G, and 227G may be disposed in the peripheral region ER to provide reference potential and shield sensing noise.

The first sensing patterns 225R may extend between the sensing region SR and the first contact region CR1 or between the sensing region SR and the third contact region CR3. The first sensing patterns 225R may be connected to the controller chip 310 through the 1-1 sensing vias 231R, the 2-1 sensing vias 233R, and the 3-1 sensing vias 235R that are disposed in the first and third contact regions CR1 and CR3. In the first contact region CR1, the 1-1 sensing vias 231R, the 2-1 sensing vias 233R, and the 3-1 sensing vias 235R may be arranged in the first direction (X-direction). In addition, in the third contact region CR3, each of the 1-1 sensing vias 231R, the 2-1 sensing vias 233R, and the 3-1 sensing vias 235R may be arranged in the first direction (X-direction). Some of the first sensing patterns 225R may be connected to the 1-1 sensing vias 231R, the 2-1 sensing vias 233R, and the 3-1 sensing vias 235R disposed in the first contact region CR1. In addition, others of the first sensing patterns 225R may be connected to the 1-1 sensing vias 231R, the 2-1 sensing vias 233R, and the 3-1 sensing vias 235R that are disposed in the third contact region CR3. The neighboring first sensing patterns 225R may be electrically separated from each other.

The second sensing patterns 227T may extend in the sensing region SR and the second contact region CR2. The second sensing patterns 227T may be connected to the controller chip 310 through the 1-2 sensing vias 231T, the 2-2 sensing vias 233T, the 3-2 sensing vias 235T, and the 4-2 sensing vias 237T that are disposed in the second contact region CR2. Each of the 1-2 sensing vias 231T, the 2-2 sensing vias 233T, the 3-2 sensing vias 235T, and the 4-2 sensing vias 237T may be alternately arranged in a zigzag pattern in the second direction (Y-direction). For example, the 1-2 sensing vias 231T, the 2-2 sensing vias 233T, the 3-2 sensing vias 235T, and the 4-2 sensing vias 237T may have an alternating arrangement along the second direction (Y-direction).

The first sensing patterns 225R may have a first width W1 in the first direction (X-direction), and the second sensing patterns 227T may have a second width W2 in the second direction (Y-direction). In example embodiments of the present inventive concept, the first width W1 may be greater than the second width W2. For example, the first width W1 may range from approximately 2 to 4 times the second width W2. For example, the first width W1 may range from about 40 μm to about 70 μm, and the second width W2 may range from about 5 μm to about 25 μm.

A portion in which the first sensing patterns 225R and the second sensing patterns 227T overlap each other in the third direction (Z-direction) may be included in the pixels PX. A first pitch PIX in the first direction (X-direction) between centers PXC of the pixels PX may be substantially the same as a second pitch PIY in the second direction (Y-direction) between centers PXC of the pixels PX, but an example embodiments of the present inventive is not limited thereto. For example, each of the first pitch PIX and the second pitch PIY may range from about 50 μm to about 90 μm.

Pixels PX may have a composite capacitance value based on area capacitance AC, which is based on the first sensing patterns 225R and the second sensing patterns 227T overlapping each other, and fringing capacitance, which is based on the first sensing patterns 225R and the second sensing patterns 227T overlapping each other.

When a fingerprint of a user comes into contact with the upper surface 200U of the substrate 200, a capacitance value corresponding to each pixel PX may change due to capacitance induced between the second sensing patterns 227T and a fingerprint of a user. Since the change in capacitance value is determined by a shape of a fingerprint of a user, the controller chip 310 may identify a fingerprint of a user from the change in the capacitance value of the pixels PX.

The fourth ground pattern 227G may surround the sensing region SR in which the second sensing patterns 227T are disposed. The fourth ground pattern 227G may be disposed on substantially the same vertical level as that of the second sensing patterns 227T, and may surround the second sensing patterns 227T in a planar manner. For example, the fourth ground pattern 227G may extend continuously along an edge of the sensing region SR on the upper surface of the upper insulating layer 215, and may surround the second sensing patterns 227T. The fourth ground pattern 227G may be disposed around the sensing region SR and may function to reduce sensing noise while a fingerprint of a user touches the sensing region SR.

The base layer 211 may include an insulating material. The base layer 211 may include resin and glass fiber. For example, the resin included in the base layer 211 may be at least one of phenol resin, epoxy resin, and polyimide. In some example embodiments, the base layer 211 may include at least one selected from flame retardant 4 (FR4), tetrafunctional epoxy, polyphenylene ether, epoxy/polyphenylene oxide, Thermount, bismaleimide triazine (BT), cyanate ester, polyimide, prepreg, Ajinomoto build-up film (ABF), and/or liquid crystal polymer. In example embodiments of the present inventive concept, the base layer 211 may include silicon oxide, silicon nitride, silicon oxynitride, or a combination thereof. The glass fiber included in the base layer 211 may be a reinforcing material and may be obtained by focusing glass filament obtained by melt-spinning a glass material at high temperature. Glass filament may be a processed ore product including silica as a main component.

In the description below, for ease of description, the components of the substrate 200 will be described in the order of proximity to the base layer 211.

The second conductive layers 223G and 223R, and 223T may include 2-1 sensing pads 223R, 2-2 sensing pads 223T, and a second ground pattern 223G to which a reference potential is applied. The second ground pattern 223G may be disposed in the sensing region SR, the wiring region YR, and the peripheral region ER. A portion of the second ground pattern 223G may overlap with the first sensing patterns 225R and the second sensing patterns 227T in the third direction (Z-direction). A portion of the second ground pattern 223G may be interposed between the second sensing patterns 227T and the controller chip 310. Accordingly, the second ground pattern 223G may block external sensing noise from the controller chip 310. The 2-1 sensing pads 223R may be disposed in the first and third contact regions CR1 and CR3, and the 2-2 sensing pads 223T may be disposed in the second contact region CR2. The 2-1 sensing pads 223R may provide a path for electrically connecting the first sensing patterns 225R to the controller chip 310, and the 2-2 sensing pads 223T may provide a path for electrically connecting the second sensing patterns 227T to the controller chip 310.

The lower insulating layer 213 may be disposed on a surface of the base layer 211 to cover the second conductive layers 223G and 223R, and 223T. The lower insulating layer 213 may electrically isolate the 2-1 sensing pads 223R, the 2-2 sensing pads 223T, and the second ground pattern 223G from each other.

The third conductive layer 225G and 225R, and 225T may include a third ground pattern 225G to which a reference potential is applied, first sensing patterns 225R for recognizing fingerprint of a user, and 3-2 sensing pads 225T. The first sensing patterns 225R may be disposed in the sensing region SR, and the third ground pattern 225G may be disposed in the wiring region YR and the peripheral region ER. The 3-2 sensing pads 225T may be disposed in the second contact region CR2. The 3-2 Sensing pads 225T may provide a path for electrically connecting the second sensing patterns 227T to the controller chip 310.

The upper insulating layer 215 may be disposed on an upper surface of the base layer 211 and may cover the third conductive layers 225G and 225R, and 225T. The upper insulating layer 215 may electrically isolate the first sensing patterns 225R, the 3-2 sensing pads 225T, and the third ground pattern 223G from each other.

The lower insulating layer 213 and the upper insulating layer 215 may include different materials from each other. For example, the upper insulating layer 215 may include a material having a dielectric constant suitable for fingerprint recognition of fingerprint sensor package 10. However, an example embodiment of the present inventive concept is not limited thereto, and the lower insulating layer 213 and the upper insulating layer 215 may include the same material as each other.

Each of the lower insulating layer 213 and the upper insulating layer 215 may include at least one of, for example, phenol resin, epoxy resin, and/or polyimide. In example embodiments of the present inventive concept, each of the lower insulating layer 213 and the upper insulating layer 215 may include at least one of prepreg, FR4, quadrilateral epoxy, polyphenylene ether, epoxy/polyphenylene oxide, Thermount, BT, cyanate ester, polyimide, and/or liquid crystal polymer.

The fourth conductive layers 227G and 227T may be disposed on an upper surface of the upper insulating layer 215. The fourth conductive layer 227G and 227T may include a fourth ground pattern 227G to remove sensing noise and a second sensing pattern 227T to recognize fingerprint of a user. The second sensing patterns 227T may be disposed in the sensing region SR, and the fourth ground pattern 227G may be disposed in the peripheral region ER.

The second sensing patterns 227T may be spaced apart from the first sensing patterns 225R in the third direction (Z-direction) with the insulating layer 215 interposed therebetween. In other words, the second sensing patterns 227T may be electrically insulated from the first sensing patterns 225R by the upper insulating layer 215. Accordingly, the first sensing patterns 225R may be included in a first electrode of the capacitor, and the upper insulating layer 215 may be included in the dielectric layer of the capacitor. In addition, the second sensing patterns 227T may be included in the second electrode of the capacitor. For example, capacitors included in a fingerprint sensor may be formed in the substrate 200.

The upper protective layer 219 may be disposed on an upper surface of the upper insulating layer 215 and may cover the fourth conductive layers 227G and 227T.

The first conductive layer 221B, 221G, 221R, 221T, and 221P may be disposed on a surface of the lower insulating layer 213. The first conductive layers 221B, 221G, 221R, 221T, and 221P may include second bonding pads 221B, 1-1 sensing pads 221R, 1-2 sensing pads 221T, and a first ground pattern 221G to which a reference potential is applied.

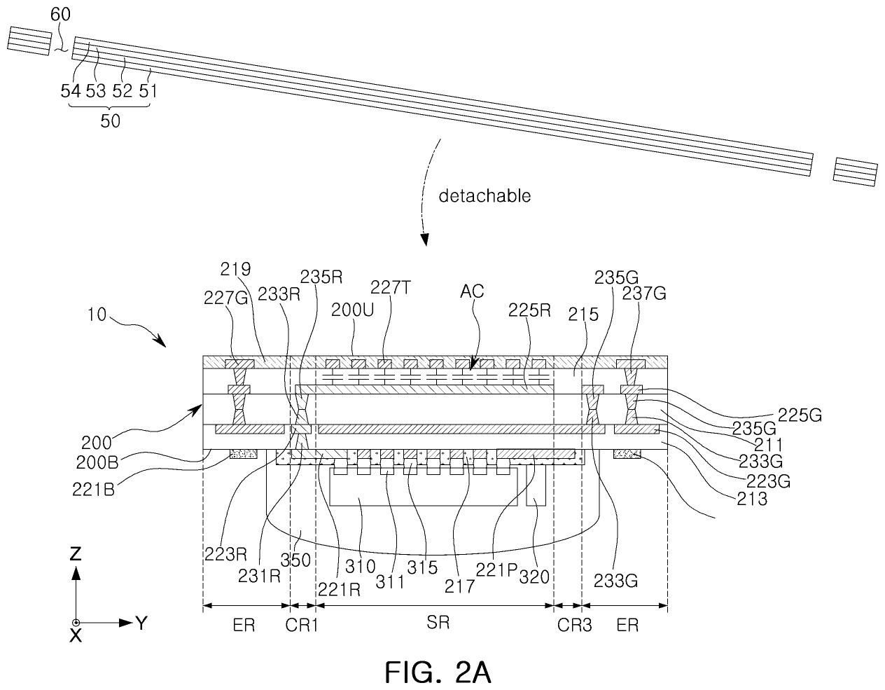

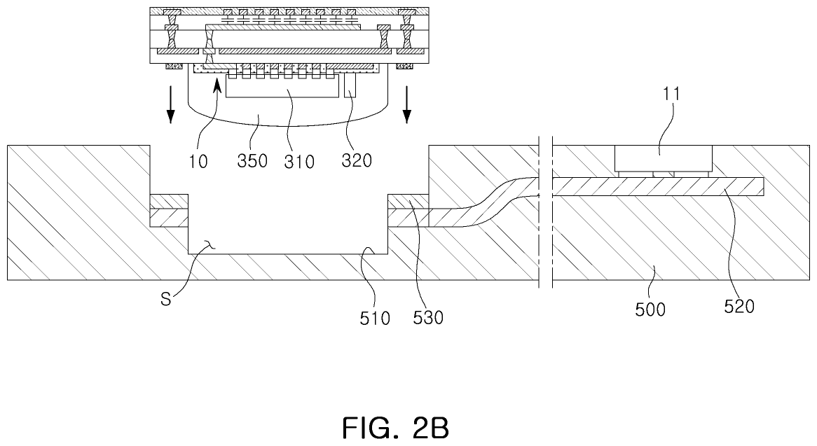

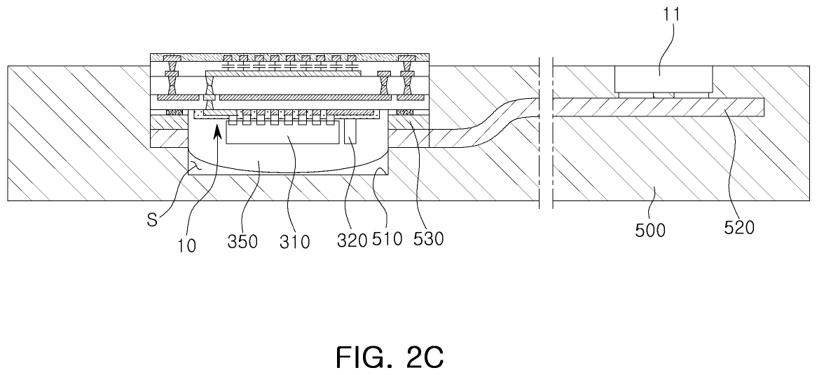

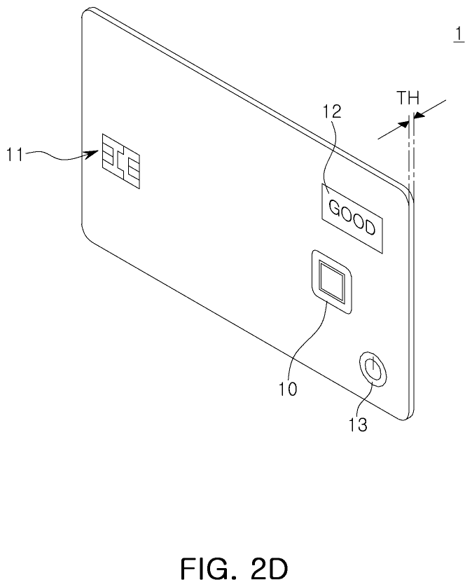

The second bonding pads 221B may include a power pad, to which power (e.g., power potential) provided from an external device is applied, a ground pad, to which reference potential is applied, and an output pad for outputting results of fingerprint recognition of the fingerprint sensor package 10 externally (e.g., the display portion 12 of the device 1 in FIG. 2D). The controller chip 310 may receive power potential through the pad and power pattern 221P of a portion of the second bonding pads 221B, and may receive reference potential through a pad and the first ground pattern 221G of a portion of the second bonding pads 221B. In addition, the controller chip 310 may receive signals recognized from the first and second sensing patterns 225R and 227T through the 1-1 sensing pads 221R and the 1-2 sensing pads 221T.

The 1-1 sensing pads 221R may extend from the first and third contact regions CR1 and CR3 to a portion overlapping the controller chip 310 in the third direction (Z-direction), and the 1-2 sensing pads 221T may extend from the second contact region CR2 to a portion overlapping the controller chip 310 in the third direction (Z-direction). The 1-1 sensing pads 221R may provide a path for electrically connecting the first sensing patterns 225R to the controller chip 310, and the 1-2 sensing pads 221T may provide a path for electrically connecting the second sensing patterns 227T and the controller chip 310.

The lower protective layer 217 may be disposed on a surface of the lower insulating layer 213 and may cover at least a portion of the first conductive layer 221B, 221G, 221R, 221T, and 221P. In example embodiments of the present inventive concept, the lower protective layer 217 may be formed to cover some regions of a lower surface of the lower insulating layer 213. In example embodiments of the present inventive concept, the lower protective layer 217 may be formed to entirely cover a lower surface of the lower insulating layer 213.

Each of the lower protective layer 217 and the upper protective layer 219 may be an insulating coating layer. In example embodiments of the present inventive concept, the lower protective layer 217 and the upper protective layer 219 may be formed of solder resist. In example embodiments of the present inventive concept, the lower protective layer 217 and the upper protective layer 219 may include polymer material having excellent heat resistance, insulation, and hardness. For example, each of the lower protective layer 217 and the upper protective layer 219 may be formed of polyimide, polyamide, polyacetal, polycarbonate. In an example embodiment of the present inventive concept, the upper protective layer 219 in contact with a fingerprint of a user may be formed of a material having higher hardness than that of the lower protective layer 217 to protect against external influences such as contamination, impacts, and scratches. For example, the upper protective layer 219 and the lower protective layer 217 may be formed of solder resist, and the upper protective layer 219 may be formed of high hardness solder resist having a hardness of 4H or more. In example embodiments of the present inventive concept, the upper protective layer 219 may include a material (e.g., a high-κ material) having a dielectric constant suitable for fingerprint recognition.

The controller chip 310 and the passive component 320 may be disposed on the surface of the substrate 200. The controller chip 310 may be mounted on a surface of the substrate 200 by using a flip chip method. Connection bumps 315 may electrically and physically connect the controller chip 310 to the substrate 200 and may be disposed between the controller chip 310 and the substrate 200. The connection bumps 315 may be disposed between a portion of patterns of the first conductive layer 221B, 221G, 221R, 221T, and 221P and the chip pads 311 of the controller chip 310.

In example embodiments of the present inventive concept, the controller chip 310 may be disposed entirely or partially in the sensing region SR. In example embodiments of the present inventive concept, the controller chip 310 may be disposed outside of the sensing region SR. The controller chip 310 may include any components for performing computation to recognize a fingerprint of a user from changes in the capacitance value of the pixels PX. For example, the controller chip 310 may include a memory chip and/or a processor chip. In addition, the passive component 320 may include, for example, a multilayer ceramic capacitor (MLCC), but an example embodiment of the present inventive concept is not limited thereto.

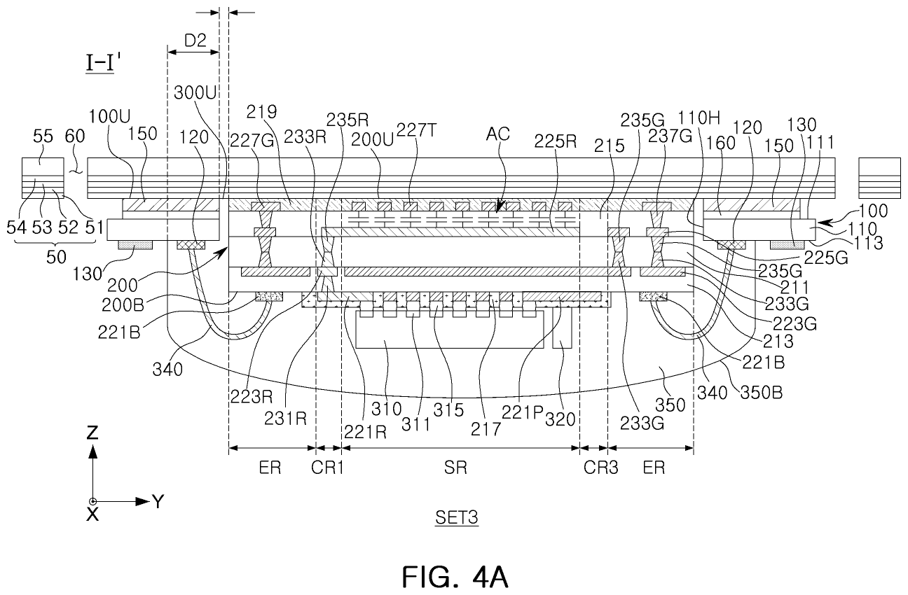

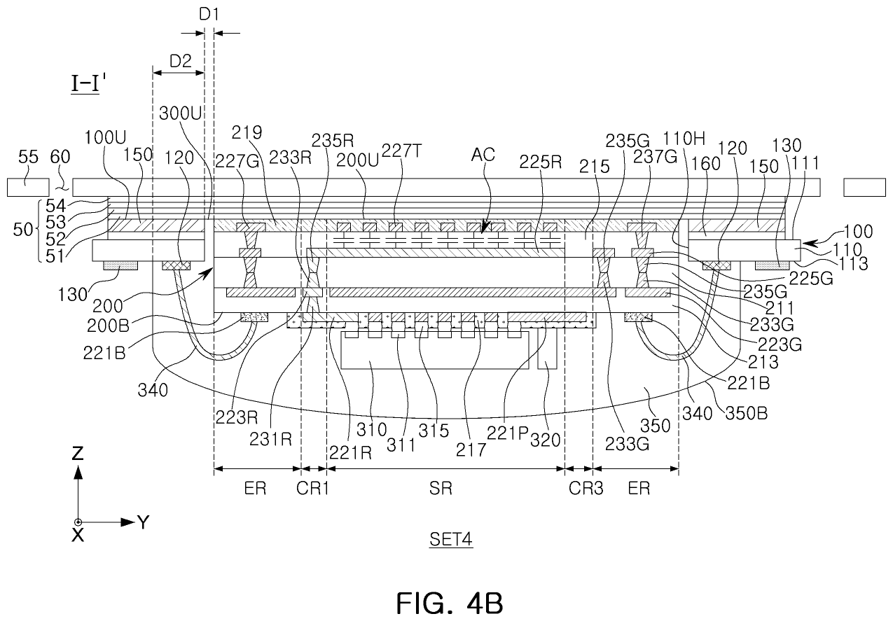

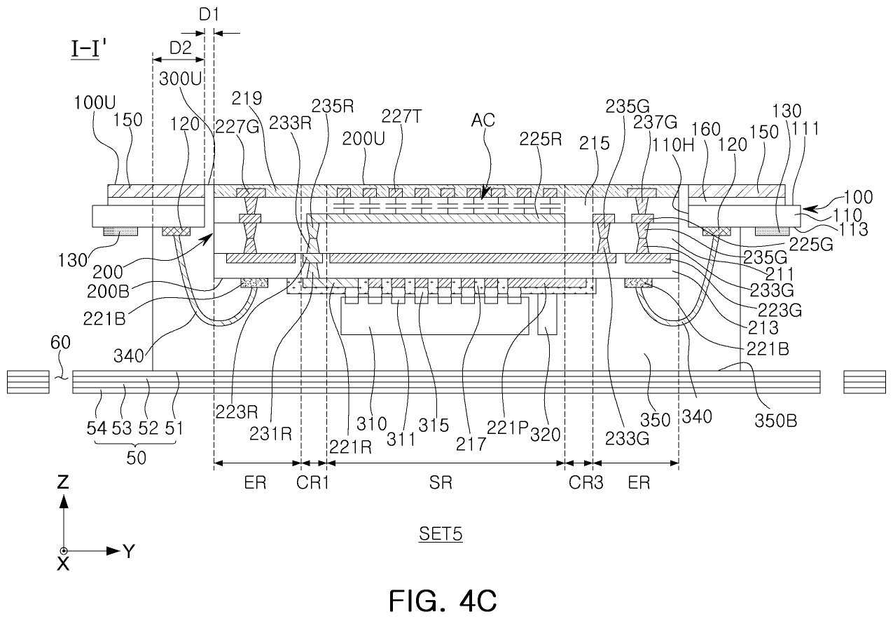

The first molding layer 350 may be disposed on the substrate 200 and may cover the controller chip 310 and the passive component 320. The first molding layer 350 may protect the substrate 200, the controller chip 310 and the passive component 320 from external influences such as contamination and impacts. The upper surface 350U of the first molding layer 350 may be formed to be substantially coplanar with an upper surface 200U of the substrate 200 (see, e.g., FIGS. 3C, 3D, 3E, 4A, 4B, and 4C). However, an example embodiment of the present inventive concept is not limited thereto, and in example embodiments of the present inventive concept, the upper surface 350U of the first molding layer 350 may be formed to be concave due to meniscus that is generated during the manufacturing process. A central portion of the first molding layer 350 may have a thickness greater than that of an edge of the molding layer 350. In other words, the lower surface 350B (see, e.g., FIGS. 3C, 3D, 3E, 4A, 4B, and 4C) of the first molding layer 350 may be formed to be convex. For example, a thickness T1 of the central portion of the first molding layer 350 may be greater than a thickness T2 in an upper portion of the sidewall of the substrate 200.

The first molding layer 350 may be formed of an epoxy molding compound. In addition, the first molding layer 350 may be formed of an epoxy-based material, a thermosetting material, a thermoplastic material, or a UV-treated material.

In the fingerprint sensor package 10 according to an example embodiment of the present inventive concept, the substrate 200 may include a sensing region SR corresponding to a fingerprint recognition sensor, such that an overall thickness may be reduced and may be used to manufacture a smart card having a thickness that is equivalent to that of conventional credit and debit cards. In addition, in the fingerprint sensor package 10 according to an example embodiment of the present inventive concept, the sensing region SR of the substrate 200 may be exposed and may be in direct contact with fingerprint of a user, such that reliability and sensitivity of obtaining fingerprint information may be increased.

The fingerprint sensor package 10 according to an example embodiment of the present inventive concept may have a total thickness of about 0.76 mm or less. In example embodiments of the present inventive concept, the total thickness of the fingerprint sensor package 10 may be about 0.5 mm or less. For example, the total thickness of the fingerprint sensor package 10 may range from about 0.1 mm to 0.4 mm. Accordingly, the fingerprint sensor package 10 may be easily applied to various products that are curved or require a reduced thickness (e.g., a smart card described above).

FIG. 2A illustrates an operation of detaching a fingerprint sensor package 10 of a fingerprint sensor package carrier SET1 in FIG. 1C from a film member 50. FIGS. 2B and 2C illustrate an operation of disposing the detached fingerprint sensor package 10 in a groove region 510 of a device body 500. FIG. 2D illustrates a device 1 in which the fingerprint sensor package 10 is assembled. The detaching operation may include emitting ultraviolet rays to the fingerprint sensor package carrier SET1.

Since the fingerprint sensor package 10 may be detached from the film member 50 without a cutting process, a horizontal size of a portion of the fingerprint sensor package 10, other than the first molding layer 350, before being detached from the film member 50 may be the same as a horizontal size of a portion of the fingerprint sensor package 10, other than the first molding layer 350, after being disposed in the groove region 510 of the device body 500. In addition, the horizontal size of the substrate 200 of the fingerprint sensor package 10 before being detached from the film member 50 may be the same as the horizontal size of the substrate 200 of the fingerprint sensor package 10 after being disposed in the groove region 510 of the device body 500.

Referring to FIG. 2B, the device body 500 including a device substrate 520, a connection pad 530, and a security chip 11 may be prepared. The device body 500 may include a groove region 510 for mounting the fingerprint sensor package 10.

The device substrate 520 and the security chip 11 for storing financial information may be disposed in the device body 500. For example, an FPCB may be used as the device substrate 520. The security chip 11 may be mounted on the device substrate 520. The security chip 11 may be disposed in the device body 500 such that one surface of the security chip 11 may be exposed. In addition, a connection pad 530 for electrically connecting the fingerprint sensor package 10 to other components in the device body 500 may be disposed on the device substrate 520. The connection pad 530 may include a conductive material. The fingerprint sensor package 10 may be aligned in the groove region 510 of the device body 500 such that the upper surface 200U of the substrate 200 may be exposed by the device body 530.

Referring to FIG. 2C, the fingerprint sensor package 10 may be mounted on the device body 500. At least a portion of the fingerprint sensor package 10 may be accommodated in the groove region 510 of the device body 500. The first molding layer 350 of fingerprint sensor package 10 may be accommodated in the groove region 510. In example embodiments of the present inventive concept, the groove region 510 might not be entirely filled by the first molding layer 350 of the fingerprint sensor package 10, and a movable space S may be formed between the first molding layer 350 of the fingerprint sensor package 10 and the device body 500. The movable space S may provide a space in which the fingerprint sensor package 10 may respond flexibly, depending on the degree of bending of the device 1. In example embodiments of the present inventive concept, the movable space S may be filled with an adhesive.

Referring to FIG. 2D, the device 1 may include a fingerprint sensor package 10, a security chip 11, a display portion 12, and a power button 13. The device 1 may be a smart card, but example embodiments of the present inventive concept are not limited thereto. For example, device 1 may be configured to be draped on or planted in a user of device 1, such as a wearable electronic device, or may be configured to be mounted on an electronic device having a size greater than that of the device 1 (e.g., a vehicle, a portable terminal, and the like). When a user touches the fingerprint sensor package 10 of the device 1, the touched fingerprint may be recognized. When the recognized fingerprint matches the registered fingerprint, the security chip 11 may grant payment authority to the user of the device 1.

The smart card, which may be a type of the device 1, may further include information displayed on a general credit card or debit card, such as a card number identification unit, an expiration date identification unit, a user name, or the like. In example embodiments of the present inventive concept, the device 1 may further include an RF chip.

The fingerprint sensor package 10 may recognize the fingerprint when the fingerprint of the user touches the fingerprint sensor. The fingerprint sensor package 10 may compare the recognized fingerprint with registered fingerprints and may determine whether the recognized fingerprint matches the registered fingerprint. The fingerprint sensor package 10 may operate after the device 1 is turned on.

The security chip 11 may store encrypted financial information. When the recognized fingerprint matches the registered fingerprint, the security chip 11 may grant payment authority to a user of the device 1. For example, device 1 may allow the security chip 11 to grant the payment authority to the user based on the recognition results of the fingerprint sensor package 10, thereby preventing financial incidents caused by theft or loss.

The display portion 12 may display whether the recognized fingerprint matches the registered fingerprint, whether the fingerprint is turned on/off, and the like. For example, the display portion 12 may display letters, numbers, special symbols, or the like, and may further include a light emitting portion in some cases. However, depending on the type of device 1, the display portion 12 might not be provided.

The power button 13 may turn the device 1 on/off. The device 1 in a turned-off state may be switched to a turned-on state by an operation of the power button 13, and the device 1 in a turned-on state may be switched to a turned-off state by an operation of the power button 13. In addition, when a determined time elapses after the device 1 switches to a turned-on state, the device 1 may automatically switch to a turned-off state. However, depending on the type of device 1, the power button 13 might not be provided.

In example embodiments of the present inventive concept, the thickness TH of the device 1 may range from about 0.5 mm to about 1 mm. In addition, the thickness TH of the device 1 may be about 0.84 mm or less in accordance with international standards. For example, the thickness TH of the device 1 may be about 0.76 mm or less.

A smart card, which may be a type of device 1, may include a fingerprint sensor package 10 and may have the same level of thickness as that of a conventional credit or debit card, and accordingly, the way traditional credit or debit cards are used may be maintained, and a high level of security may be provided to a user.

FIGS. 3A to 3D illustrate a fingerprint sensor package carrier SET2 having a structure in which an edge substrate 100 is added to the fingerprint sensor package carrier SET1 in FIGS. 1A to 1D. FIGS. 3E to 3G illustrate a process of assembling the fingerprint sensor package 10 having an additional edge substrate 100. The fingerprint sensor package carrier SET2 and the fingerprint sensor package assembly method illustrated in FIGS. 3A to 3G may be almost the same as or similar to the fingerprint sensor package carrier SET1 and the fingerprint sensor package assembly method described with reference to FIGS. 1A to 2D, other than the edge substrate 100. In the description below, the fingerprint sensor package carrier SET2 and the fingerprint sensor package assembly method in FIGS. 3A to 3G will be described, focusing on differences from the fingerprint sensor package carrier SET1 described with reference to FIGS. 1A to 2D. Redundant descriptions may be omitted or briefly discussed.

Referring to FIGS. 3A to 3G, the fingerprint sensor package carrier SET2 according to an example embodiment of the present inventive concept may further include an edge substrate 100. The substrate 200 may be accommodated in the surrounding space 110H of the edge substrate 100 and may be electrically connected to the edge substrate 100 through the conductive wires 340.

The upper surface 200U of the substrate 200 may be disposed to be substantially coplanar with the upper surface 100U of the edge substrate 100. Accordingly, when a fingerprint of a user is in contact with the upper surface 100U of the edge substrate 100, the user's fingerprint may be naturally connected to a ground bezel 150 of the edge substrate 100. However, in example embodiments of the present inventive concept, an upper surface of the substrate 200 may be disposed to have a level that is higher or lower than that of an upper surface 100U of the edge substrate 100.

The external connection pad 130 of the edge substrate 100 may be bonded to the connection pad 530 of the device substrate 520. The external connection pad 130 of the edge substrate 100 may be physically and electrically connected to the connection pad 530 of the device substrate 520. The second bonding pads 221B may be connected to conductive wires 340 and may be electrically connected to the first bonding pads 120 of the edge substrate 100 through the conductive wires 340.

The first molding layer 350 may cover the first bonding pads 120 that are disposed on a second surface 113 of a core insulating layer 110 of the edge substrate 100, and might not cover the external connection pads 130, which are be exposed. The first molding layer 350 may extend along a boundary between a region in which the first bonding pads 120 are disposed and a region in which the external connection pads 130 are disposed on the second surface 113 of the core insulating layer 110. The first molding layer 350 may extend in a lateral direction from a side surface of the substrate 200 to cover the first bonding pad 120, and may be spaced apart from the external connection pads 130. The first molding layer 350 may be formed to cover from the surrounding space 110H of the edge substrate 100 to the second distance D2. For example, the second distance D2 may range from about 0.1 mm to about 3.0 mm.

The edge substrate 100 may include a core insulating layer 110, first bonding pads 120, external connection pads 130, ground bezel 150, and an adhesive layer 160. The edge substrate 100 may include a printed circuit board (PCB). In example embodiments of the present inventive concept, the edge substrate 100 may include a flexible PCB (FPCB) having flexibility to be bent. In example embodiments of the present inventive concept, the edge substrate 100 may include a rigid-type PCB.

The core insulating layer 110 may have an approximately rectangular planar shape or a square planar shape, and may be provided in the form of a flexible film or plate. The core insulating layer 110 may include a first surface 111 and a second surface 113 that oppose each other. Here, the direction parallel to a pair of edges of the core insulating layer 110 may be defined as the first direction (X-direction), and the direction parallel to the other pair of edges may be defined as the second direction (Y-direction). In addition, the direction perpendicular to the main surface (the first surface 111 or the second surface 113) of the core insulating layer 110 may be defined as the third direction (Z-direction).

The core insulating layer 110 may include an insulating material. For example, the core insulating layer 110 may be a flexible film including polyimide. For example, the core insulating layer 110 may be formed of synthetic resin such as epoxy resin, acrylic, polyether nitrile, polyether sulfone, polyethylene cterephthalate, and polyethylene naphthalate.

A surrounding space 110H penetrating through the first surface 111 and the second surface 113 may be formed in an almost central portion of the core insulating layer 110. The substrate 200 may be accommodated in the surrounding space 110H, and may be formed to be smaller than the surrounding space 110H such that a sidewall of surrounding space 110H and a sidewall of substrate 200 might not be in contact with each other. In example embodiments of the present inventive concept, a first distance D1 between a side surface of the surrounding space 110H and the sidewall of the substrate 200 may range from about 0.1 mm to 3.0 mm. The surrounding space 110H may be formed in an approximately rectangular shape or a square shape.

The first bonding pads 120 may be disposed around the surrounding space 110H on the second surface 113 of the core insulating layer 110. For example, the first bonding pads 120 may be arranged along at least one of edges of the surrounding space 110H of the core insulating layer 110. The first bonding pads 120 may be connected to the conductive wires 340, and may be electrically connected to the second bonding pads 221B of the substrate 200 through the conductive wires 340.

The external connection pads 130 may be disposed on the second surface 113 of the core insulating layer 110, and may be disposed adjacent to an edge of the second surface 113 of the core insulating layer 110. In addition, the external connection pads 130 may be arranged along an edge of the second surface 113 of the core insulating layer 110. For example, the external connection pad 130 may be more adjacent to an edge of the second surface 113 of the core insulating layer 110 than the first bonding pad 120. For example, a distance between an edge of the second surface 113 of the core insulating layer 110 and the external connection pad 130 may be smaller than a distance between an edge of the second surface 113 of the core insulating layer 110 and the first bonding pad 120. The external connection pad 130 may be configured to be electrically and physically connected to an external device. The external connection pad 130 may be electrically connected to the first bonding pads 120 through a conductive pattern that is provided on or in the edge substrate 100.

For example, each of the first bonding pads 120 and the external connection pads 130 may include at least one of copper (Cu), aluminum (Al), nickel (Ni), silver (Ag), gold (Au), platinum (Pt), tin (Sn), lead (Pb), titanium (Ti), chromium (Cr), Palladium (Pd), indium (In), zinc (Zn), carbon (C), and alloys thereof.

The ground bezel 150 may be disposed on the first surface 111 of the core insulating layer 110 and may be disposed around the surrounding space 110H. For example, when the surrounding space 110H is formed in an almost central portion of the first surface 111 of the core insulating layer 110, the ground bezel 150 may be disposed in an outer portion of the first surface 111 of the core insulating layer 110. The ground bezel 150 may be disposed around the surrounding space 110H and may function to reduce sensing noise while a fingerprint of a user touches an upper surface 200U of the substrate 200 that is accommodated in the surrounding space 110H. For example, the ground bezel 150 may include a conductive material, such as a metal such as copper (Cu) or aluminum (Al).

The ground bezel 150 may be electrically grounded. In example embodiments of the present inventive concept, the ground bezel 150 may be configured to receive a reference potential through a conductive via 170 penetrating through the core insulating layer 110 and the adhesive layer 160. The conductive via 170 may be configured to electrically connect the ground bezel 150 to the external connection pad 130, and may be used as an electrical path to transmit a reference potential to the ground bezel 150.

The ground bezel 150 may extend along a perimeter of the surrounding space 110H. The ground bezel 150 may have an annular shape surrounding the surrounding space 110H in a planar manner. In example embodiments of the present inventive concept, a sidewall of the ground bezel 150 may be aligned to be substantially coplanar with a sidewall of the surrounding space 110H. In addition, in example embodiments of the present inventive concept, the ground bezel 150 may be spaced apart from the surrounding space 110H.

In example embodiments of the present inventive concept, each external side corner CN1 of the edge substrate 100 may have a rounded shape. In example embodiments of the present inventive concept, a radius of curvature of the external side corner CN1 of the edge substrate 100 may range from about 0.1 mm to about 2 mm. For example, a radius of curvature of the external side corner CN1 of the edge substrate 100 may be about 1 mm. For example, a reason that the external side corner CN1 of the edge substrate 100 may have a rounded shape may be to effectively prevent cracks from occurring in the external side corner CN1 during a process of cutting the first panel substrate by using a punching device.

The fingerprint sensor package carrier SET3, SET4, and SET5 illustrated in FIGS. 4A to 4C may be substantially the same as or similar to the fingerprint sensor package carrier SET1 described with reference to FIGS. 1A to 1E other than the film member 50. In the description below, the fingerprint sensor package carriers SET3, SET4, and SET5 in FIGS. 4A to 4C will be described, focusing on differences from the fingerprint sensor package carrier SET1 described with reference to FIGS. 1A to 1E. Redundant descriptions may be omitted or briefly discussed.

Referring to FIGS. 4A and 4B, the film member 50 of the fingerprint sensor package carriers SET3 and SET4 may further include a support film 55. The support film 55 may have substantially no adhesiveness or may have an adhesiveness lower than that of the adhesive layer 52. For example, the support film 55 may be a flexible film including polyimide or a flexible printed circuit board (flexible PCB). In addition, the support film 55 may be formed of synthetic resin such as epoxy resin, acrylic, polyether nitrile, polyether sulfone, polyethylene terephthalate, and polyethylene naphthalate.

The support film 55 may include a plurality of through-holes 60 formed in sides (e.g., the Y-direction side) thereof. Accordingly, the support film 55 may be efficiently provided to an infrastructure assembling the plurality of fingerprint sensor packages 10 into corresponding devices in a reel-to-reel manner. For example, teeth of a sprocket included in the infrastructure may be inserted into the plurality of through-holes 60, and the sprocket may wind or unwind the support film 55 by rotating. When the support film 55 is wound or unwound by the sprocket, the plurality of fingerprint sensor packages 10 may be provided flexibly by being attached to the film member 50. Subsequently, the plurality of fingerprint sensor packages 10 may be detached from the film member 50 to be assembled into devices.

Referring to FIG. 4A, the plurality of through-holes 60 of the film member 50 may be formed in at least one of the release layer 51, the adhesive layer 52, the resin layer 53 and the film 54, and may also be formed in the support film 55. Referring to FIG. 4B, the plurality of through-holes 60 of the film member 50 may be formed in the support film 55, and might not be formed in the release layer 51, the adhesive layer 52, the resin layer 53 and the film 54. A horizontal area (e.g. the X-Y plane area) of each of the release layer 51, the adhesive layer 52, the resin layer 53 and the film 54 may be smaller than a horizontal area of the support film 55.

Referring to FIG. 4C, the film member 50 of the fingerprint sensor package carrier SET5 may be attached to the first molding layer 350. By detaching the first molding layer 350 from the film member 50, the fingerprint sensor package 10 may be detached from the film member 50. That is, in example embodiments of the present inventive concept, the substrate 200 may be spaced apart from the film member 50. That is, in example embodiments of the present inventive concept, the substrate 200 and/or the edge substrate 100 might not be an object which may be detached by the film member 50 being in direct contact therewith.

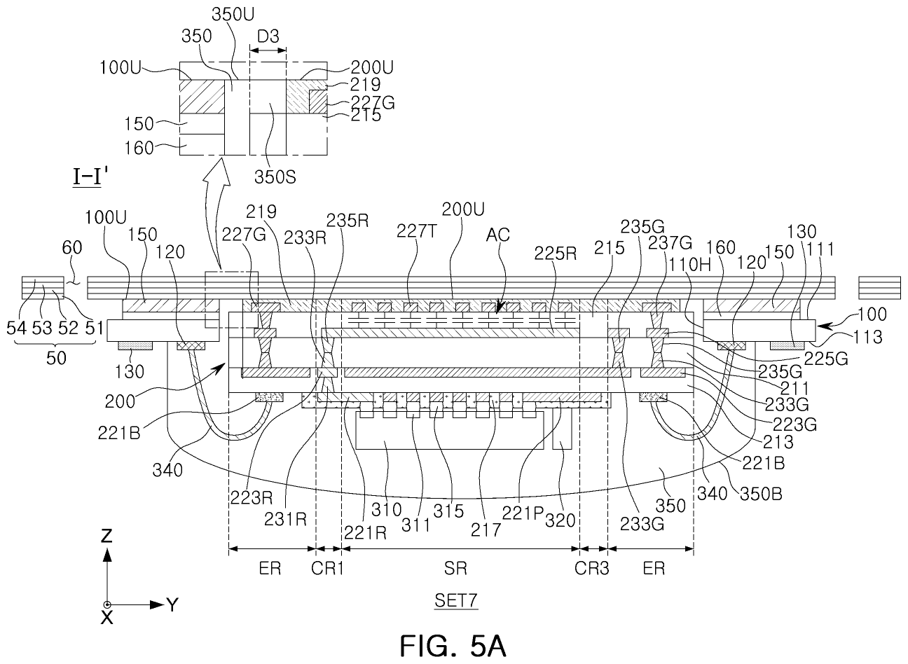

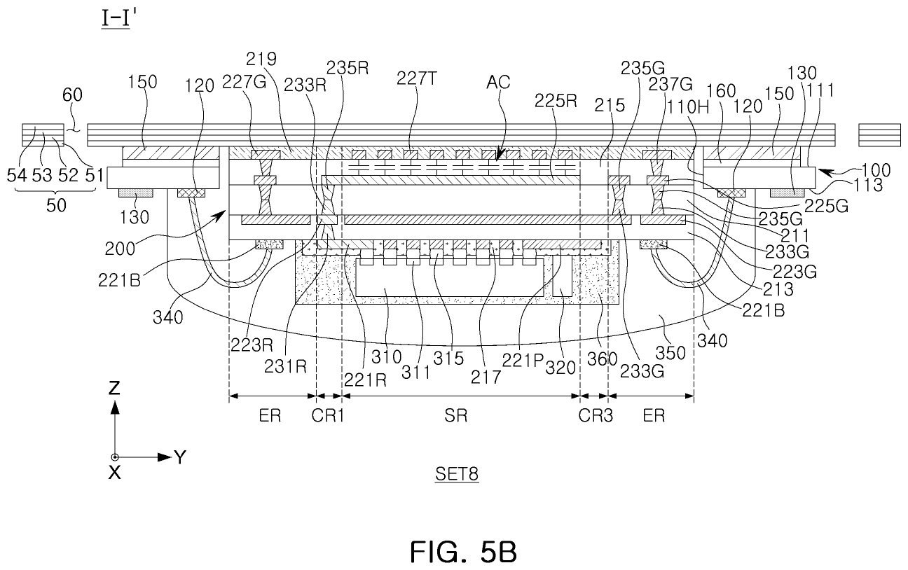

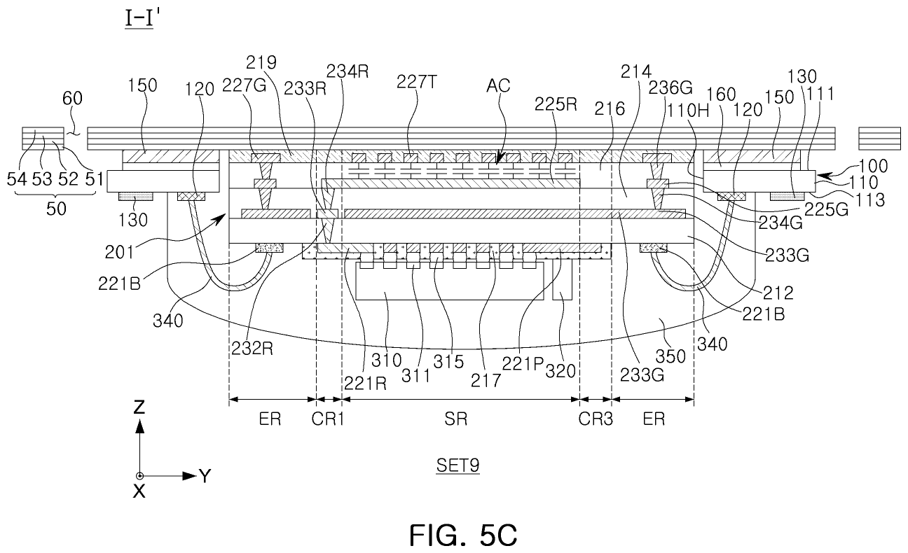

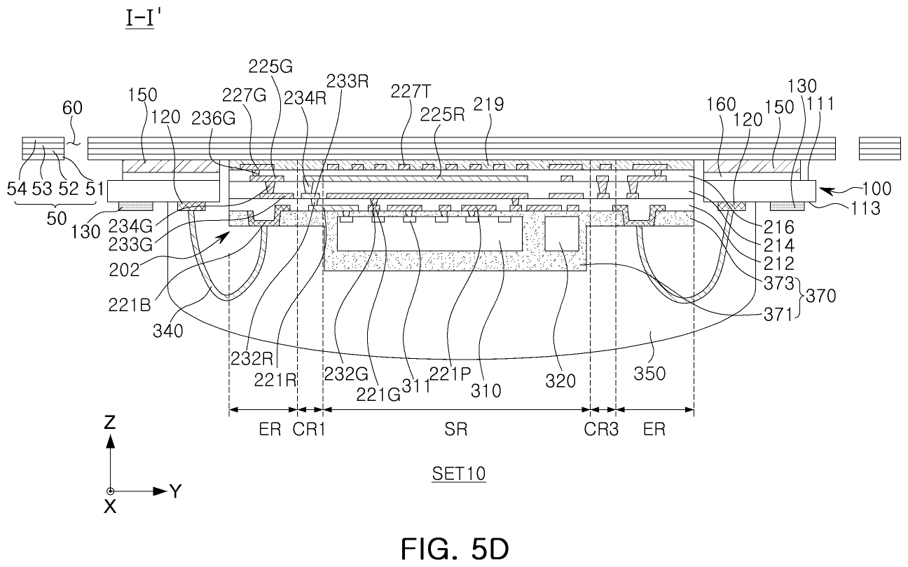

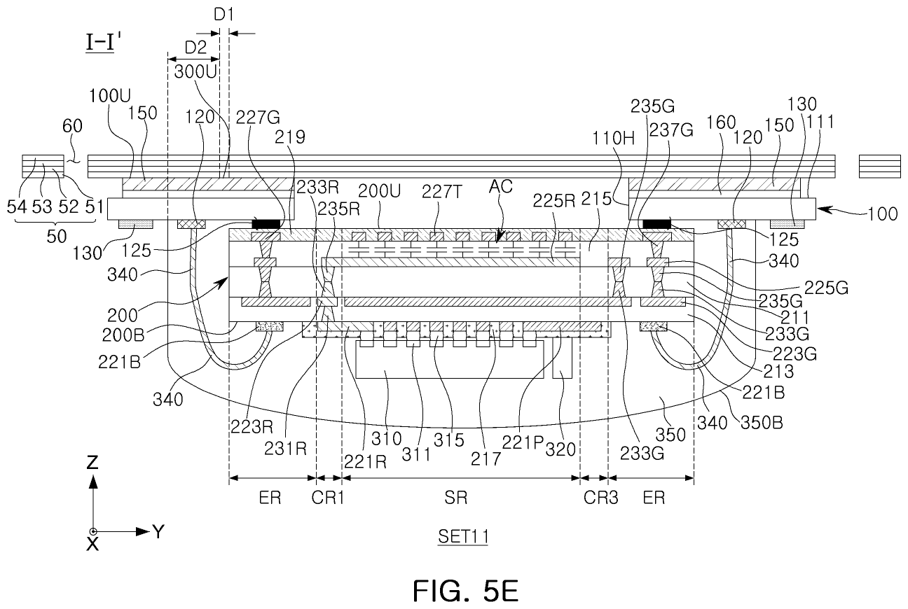

The fingerprint sensor package carrier SET7 illustrated in FIG. 5A may be substantially the same as or similar to the fingerprint sensor package carrier SET1 described with reference to FIGS. 1A to 1E except that a portion of the upper protective layer 219 of the substrate 200 is removed. In the description below, the fingerprint sensor package carrier SET7 in FIG. 5A will be described, focusing on differences from the fingerprint sensor package carrier SET1 described with reference to FIGS. 1A to 1E. Redundant descriptions may be omitted or briefly discussed.

Referring to FIG. 5A, the upper protective layer 219 may be formed to cover a partial region of the upper surface 200U of the substrate 200 and may be spaced apart from edges of the upper surface 200U of the substrate 200. For example, the upper protective layer 219 may be spaced apart from a side surface of the substrate 200 by a third distance D3. An upper surface of the upper protective layer 219 may be substantially coplanar with the upper surface 100U of the edge substrate 100. In addition, since an upper surface of the upper protective layer 219 refers to the same surface as the upper surface 200U of the substrate 200, the upper surface 200U of the substrate 200 may be substantially coplanar with the upper surface 100U of the edge substrate 100. In addition, the upper surface of the upper protective layer 219 may be substantially coplanar with the upper surface 350U of the first molding layer 350.

The first molding layer 350 may fill the surrounding space 110H and may be disposed on the side surface of the substrate 200. In addition, the first molding layer 350 may be formed by extending to the upper surface 200U of the substrate 200. For example, the first molding layer 350 may cover the region of the upper surface 200U of the substrate 200 from which the upper protective layer 219 has been removed, and may form a step portion 350S. The step portion 350S of the first molding layer 350 may cover the upper surface 200U of the substrate 200 and may fix the first molding layer 350 to the substrate 200. For example, the first molding layer 350 may be disposed on the upper insulating layer 215 and may cover a side surface of the upper protective layer 219.

The fingerprint sensor package carrier SET8 illustrated in FIG. 5B may be substantially the same or similar to the fingerprint sensor package carrier SET1 described with reference to FIGS. 1A to 1E other than the configuration in which a second molding layer 360 is additionally included. In the description below, the fingerprint sensor package carrier SET8 in FIG. 5b will be described, focusing on differences from the fingerprint sensor package carrier SET1 described with reference to FIGS. 1A to 1E. Redundant descriptions may be omitted or briefly discussed.

Referring to FIG. 5B, the second molding layer 360 may be disposed on the surface of the substrate 200 and may cover the controller chip 310 and the passive component 320. During the process of manufacturing the fingerprint sensor package carrier SET8, the first molding layer 350 may be formed after the second molding layer 360 is formed. The second molding layer 360 may be formed on a surface of the substrate 200 to cover the controller chip 310 and the passive component 320, and the first molding layer 350 may be formed to cover the second molding layer 360. The second molding layer 360 may be present between the controller chip 310 and the first molding layer 350, and between the passive component 320 and the first molding layer 350. For example, the second molding layer 360 may be formed of an epoxy molding compound. In addition, the second molding layer 360 may be formed of an epoxy-based material, a thermosetting material, a thermoplastic material, or a UV-treated material. In example embodiments of the present inventive concept, the first molding layer 350 may be formed of a transparent material or a transparent material. As the first molding layer 350 is formed of a transparent or semi-transparent material, a shape of the second molding layer 360 may be viewed externally.

The fingerprint sensor package carrier SET9 illustrated in FIG. 5C may be substantially the same or similar to the fingerprint sensor package carrier SET1 described with reference to FIGS. 1A to 1E except for the substrate 201. In the description below, the fingerprint sensor package carrier SET9 in FIG. 5C will be described, focusing on differences from the fingerprint sensor package SET1 described with reference to FIGS. 1A to 1E. Redundant descriptions may be omitted or briefly discussed.

Referring to FIG. 5C, the fingerprint sensor package carrier SET9 may include an edge substrate 100, a substrate 201, a controller chip 310, a passive component 320, and a first molding layer 350.

The substrate 201 might not include a base layer. The substrate 201 may be an insulating material and may include first to third insulating layers 212, 214, and 216. The substrate 201 may include first conductive vias 232R, which are disposed in the first insulating layer 212, second conductive vias 234G and 234R, which are disposed in the second insulating layer 214, and third conductive vias 236G, which are disposed in the third insulating layer 216. The first conductive vias 232R, the second conductive vias 234G and 234R, and the third conductive vias 236G may each have a tapered structure toward a lower surface of the substrate 201 that is in contact with the controller chip 310.

The first insulating layer 212 may be disposed on the lower protective layer 217. The first conductive vias 232R may penetrate through the first insulating layer 212 and may be in contact with the first conductive layers 221B, 221R, 221P, which are disposed on a surface of the first insulating layer 212, and the second conductive layers 233G and 233R, which are disposed on an upper surface of the first insulating layer 212.

The second insulating layer 214 may be disposed on the first insulating layer 212. The second conductive layers 223G and 223R may be covered by the second insulating layer 214. The second conductive vias 234G and 234R may penetrate through at least a portion of the second insulating layer 214, and may be in contact with the second conductive layer 233G and 233R, which are disposed on an upper surface of first insulating layer 212, and the third conductive layer 225G and 225R, which are disposed on an upper surface of second insulating layer 214.

The third insulating layer 216 may be disposed on the second insulating layer 214. The third conductive layer 225G and 225R may be covered by the third insulating layer 216. The third conductive vias 236G may penetrate through at least a portion of the third insulating layer 216, and may be in contact with the third conductive layer 225G and 225R, which are disposed on an upper surface of the second insulating layer 214, and the fourth conductive layer 227G and 227T, which are disposed on an upper surface of the third insulating layer 216.

The fingerprint sensor package carrier SET10 illustrated in FIG. 5D may be substantially the same or similar to the fingerprint sensor package carrier SET1 described with reference to FIGS. 1A to 1E except for the substrate 202. In the description below, the fingerprint sensor package carrier SET10 in FIG. 5D will be described, focusing on differences from the fingerprint sensor package carrier SET1 described with reference to FIGS. 1A to 1E. Redundant descriptions may be omitted or briefly discussed.

Referring to FIG. 5D, the fingerprint sensor package carrier SET10 may include an edge substrate 100, a substrate 202, a controller chip 310, a passive component 320, a conductive wire 340, a first molding layer 350, and a second molding layer 370. The fingerprint sensor package carrier SET10 may have a fan-out wafer level package (FO-WLP) structure.

The substrate 202 may not include a base layer. The substrate 202 may include first to third insulating layers 212, 214, and 216 sequentially stacked, and a wiring structure. The wiring structure may include first conductive layers 221B, 221G, 221P, and 221R, second conductive layers 233G and 233R, third conductive layers 225G and 225R, and fourth conductive layers 227G and 227T. In addition, the wiring structure may include first conductive vias 232G and 232R, second conductive vias 234G and 234R, and third conductive vias 236G, which have a tapered shape. In example embodiments of the present inventive concept, the wiring structure may be formed by a dual damascene process.

The second molding layer 370 may include a step difference that is formed by partially removing a flat mold material layer. The second molding layer 370 may include a first molding portion 371, which protects the controller chip 310 and the passive component 320, and a second molding portion 373, which surrounds the first molding portion 371. The second molding portion 373 may extend along a lower surface of the first insulating layer 212.

The second bonding pad 221B may be exposed through the second molding portion 373. For example, the second bonding pad 221B may be disposed in an opening that is formed in the second molding portion 373. A first segment of the second bonding pad 221B may extend to an upper surface of the second molding portion 373 and may be in contact with the first insulating layer 212. A second segment of the second bonding pad 221B may extend along an internal wall of the second molding portion 373, which may define an opening that is formed in the second molding portion 373, and a third segment of the second bonding pad 221B may extend at the same level as a lower surface of the second molding portion 373. The conductive wire 340 may be connected to the third segment of the second bonding pad 221B.

The fingerprint sensor package carrier SET11 illustrated in FIG. 5E may be substantially the same as or similar to the fingerprint sensor package carrier SET1 described with reference to FIGS. 1A to 1E other than the edge substrate 100. In the description below, the fingerprint sensor package carrier SET11 in FIG. 5E will be described, focusing on differences from the fingerprint sensor package carrier SET1 described with reference to FIGS. 1A to 1E. Redundant descriptions may be omitted or briefly discussed.

Referring to FIG. 5E, a portion of the edge substrate 100 of the fingerprint sensor package carrier SET11 may overlap the substrate 200 vertically. The film member 50 may be spaced apart from the substrate 200 and may have adhesiveness, such that the substrate 200 may be detached from the film member 50. For example, the ground bezel 150 of the edge substrate 100 may be in direct contact with the film member 50 and may be detached from the film member 50. The edge adhesive portion 125 may be adhered between the edge substrate 100 and the substrate 200. For example, the edge adhesive portion 125 may include the same adhesiveness material as an adhesiveness material that is included in the adhesive layer 52, and may have an annular shape, or a shape in which a plurality of polygons (or circles) are arranged to surround the surrounding space 110H.

According to the aforementioned example embodiments of the present inventive concept, the fingerprint sensor package carrier may increase efficiency/reliability by providing the plurality of fingerprint sensor packages, and the fingerprint sensor package assembly method may increase efficiency/reliability of assembling the fingerprint sensor package to the device body.

While the present inventive concept has been described with reference to embodiments thereof, it will be understood by those of ordinary skill in the art that various changes in form and details may be made thereto without departing from the spirit and scope of the present inventive concept.

What is claimed is:

1. A fingerprint sensor package carrier, comprising:
a film member including a plurality of through-holes formed in sides of the film member; and
a plurality of fingerprint sensor packages arranged between the sides of the film member,
wherein each of the plurality of fingerprint sensor packages includes a substrate and a controller chip disposed on the substrate,
wherein the substrate of each of the plurality of fingerprint sensor packages includes a plurality of first sensing patterns and a plurality of second sensing patterns, wherein the plurality of first sensing patterns are spaced apart from each other in a first direction and extend in a second direction intersecting the first direction, and the plurality of second sensing patterns are spaced apart from each other in the second direction and extend in the first direction, and
wherein the film member has adhesiveness, such that the plurality of fingerprint sensor packages are configured to be detached from the film member.

2. The fingerprint sensor package carrier of claim 1, wherein the film member has an adhesiveness that is weakened by ultraviolet rays.

3. The fingerprint sensor package carrier of claim 1, wherein the film member includes:
a film;
a release layer disposed on the film;
an adhesive layer disposed between the release layer and the film; and
a resin layer disposed between the adhesive layer and the film,
wherein at least one of the film, the release layer, the adhesive layer or the resin layer has the plurality of through-holes.

4. The fingerprint sensor package carrier of claim 1,
wherein the substrate is disposed between the controller chip and the film member, and
wherein the film member has an adhesiveness, such that the film member is configured to detach from the substrate.

5. The fingerprint sensor package carrier of claim 4, wherein each of the plurality of fingerprint sensor packages further includes:
a passive component disposed on the substrate; and
a molding layer covering the controller chip and the passive component.

6. The fingerprint sensor package carrier of claim 1, wherein each of the plurality of fingerprint sensor packages further includes:
a second molding layer covering the controller chip; and
a first molding layer covering the second molding layer.

7. The fingerprint sensor package carrier of claim 1, wherein the substrate of each of the plurality of fingerprint sensor packages further includes:
a base layer;
an upper insulating layer disposed between the base layer and the film member; and
an upper protective layer disposed between the upper insulating layer and the film member,
wherein the upper insulating layer is disposed between the plurality of first sensing patterns and the plurality of second sensing pattern, and
wherein the film member has an adhesiveness, such that upper protective layers of the plurality of fingerprint sensor packages are detachable from the film member.

8. The fingerprint sensor package carrier of claim 7, wherein the substrate of each of the plurality of fingerprint sensor packages further includes:
a lower insulating layer disposed between the base layer and the controller chip;
a lower protective layer disposed between the lower insulating layer and the controller chip;
a ground pattern disposed between the lower insulating layer and the base layer and vertically overlapping the controller chip; and
conductive vias spaced apart from the ground pattern and electrically connecting the plurality of first sensing patterns and the plurality of second sensing patterns to the controller chip.

9. The fingerprint sensor package carrier of claim 1, wherein each of the plurality of fingerprint sensor packages further includes:
an edge substrate spaced apart from the substrate and surrounding the substrate; and
conductive wires electrically connecting the edge substrate to the substrate,
wherein the film member has adhesiveness, such that at least one of the substrate or the edge substrate of each of the plurality of fingerprint sensor packages is detachable from the film member.

10. The fingerprint sensor package carrier of claim 1, wherein each of the plurality of fingerprint sensor packages further includes:
an edge substrate having a portion vertically overlapping the substrate; and
conductive wires electrically connecting the edge substrate to the substrate,
wherein the film member is spaced apart from the substrate of each plurality of fingerprint sensor package, and has adhesiveness, such that the edge substrate of each plurality of fingerprint sensor packages is detachable from the film member.

11. A fingerprint sensor package carrier, comprising:
a film member including a film, a release layer disposed on the film, and an adhesive layer disposed between the release layer and the film; and
a plurality of fingerprint sensor packages arranged on the film member,
wherein each of the plurality of fingerprint sensor packages includes a controller chip and a substrate disposed between the controller chip and the film member, and
wherein the substrate of each of the plurality of fingerprint sensor packages has a plurality of first sensing patterns and a plurality of second sensing patterns, wherein the plurality of first sensing patterns are spaced apart from each other in a first direction and extend in a second direction intersecting the first direction, and the plurality of second sensing patterns are spaced apart from each other in the second direction and extend in the first direction.

12. The fingerprint sensor package carrier of claim 11, wherein adhesiveness of the adhesive layer is weakened by ultraviolet rays.

13. The fingerprint sensor package carrier of claim 11, wherein each of the plurality of fingerprint sensor packages includes:
a second molding layer covering the controller chip; and
a first molding layer covering the second molding layer.

14. The fingerprint sensor package carrier of claim 11, wherein the substrate of each of the plurality of fingerprint sensor packages includes:
a base layer;
an upper insulating layer disposed between the base layer and the film member; and
an upper protective layer disposed between the upper insulating layer and the film member,
wherein the upper insulating layer is disposed between the plurality of first sensing patterns and the plurality of second sensing pattern, and
wherein the upper protective layer is disposed on the release layer.

15. The fingerprint sensor package carrier of claim 14, wherein the substrate of each of the plurality of fingerprint sensor packages further includes:
a lower insulating layer disposed between the base layer and the controller chip;
a lower protective layer disposed between the lower insulating layer and the controller chip;
a ground pattern disposed between the lower insulating layer and the base layer; and
conductive vias spaced apart from the ground pattern and electrically connecting the plurality of first sensing patterns and the plurality of second sensing patterns to the controller chip.

16. The fingerprint sensor package carrier of claim 11, wherein each of the plurality of fingerprint sensor packages includes:
an edge substrate spaced apart from the substrate, wherein the edge substrate surrounds the substrate or has a portion vertically overlapping the substrate; and
conductive wires electrically connecting the edge substrate to the substrate,
wherein at least one of the substrate or the edge substrate is in contact with the release layer.

17. The fingerprint sensor package carrier of claim 11,
wherein the film member further includes a support film including a plurality of through-holes formed in sides of the support film, and
wherein the film, the release layer, and the adhesive layer are disposed between the plurality of fingerprint sensor packages and the support film.

18. The fingerprint sensor package carrier of claim 17, wherein the film, the release layer, and the adhesive layer do not have the plurality of through-holes therein.

19. A fingerprint sensor package assembly method, comprising:
detaching a fingerprint sensor package from a film member, wherein the fingerprint sensor package includes a substrate, a controller chip disposed on the substrate, and a molding layer covering the controller chip; and
disposing the fingerprint sensor package in a groove region of a device body,
wherein a horizontal size of a portion of the fingerprint sensor package, other than the molding layer, before being detached from the film member is the same as a horizontal size of the portion of the fingerprint sensor package, other than the molding layer, after being disposed in the groove region of the device body.

20. The fingerprint sensor package assembly method of claim 19,
wherein the detaching includes emitting ultraviolet rays to the fingerprint sensor package or the film member,
wherein the film member has a plurality of through-holes formed in sides of the film member, and
wherein the fingerprint sensor package is disposed between the sides of the film member.
